(19) United States
(12) Patent Application Publication
(10) Pub. No.: US 2019/0363290 A1
(43) Pub. Date: Nov. 28, 2019

(54) DISPLAY DEVICE AND PRODUCTION METHOD OF SAID DISPLAY DEVICE

(71) Applicant: Sharp Kabushiki Kaisha, Sakai City, Osaka (JP)

(72) Inventor: Noriko WATANABE, Sakai City (JP)

(21) Appl. No.: 16/069,179

(22) PCT Filed: Mar. 30, 2017
(86) PCT No.: PCT/JP2017/013236

§ 371 Date: Jul. 11, 2018

(51) Int. Cl. H01L 51/52; H01L 51/00; H01L 27/32

(52) U.S. Cl. CPC H01L 51/5253; H01L 51/5275; H01L 2251/5338; H01L 27/3276; H01L 51/0097

(57) ABSTRACT

A flexible display includes an adhesive layer provided on a sealing film including a first inorganic layer, an organic layer, and a second inorganic layer, and a cover layer provided on the adhesive layer. Adhesive layers and cover layers are provided avoiding, in a folding portion, at least a region adjacent to organic EL elements in a plan view.

### TECHNICAL FIELD

The present disclosure relates to a display device and a production method of the display device.

### BACKGROUND ART

A flexible display has a configuration in which electro-optical elements are sandwiched, along with circuits that drive the electro-optical elements, other circuits, and the like, between a support body that supports these circuits and various functional layers.

The flexible display is used as a foldable display device including a flexibly deformable display portion, that is thin and light, and that is bendable.

The above-described electro-optical element includes, for example, an EL element, which is an optical element that utilizes the Electroluminescence (hereinafter referred to as EL) of a luminescent material. An EL display device using the EL element is attracting attention as a display device having a faster response speed and a wider viewing angle than that of a liquid crystal display device.

Such a display device includes a display panel and a functional film. The display panel includes a resin film (a resin film substrate) including a barrier layer formed on a surface thereof and formed from polyimide and the like, optical elements such as thin film transistors (TFTs) and organic EL elements, and a sealing layer covering the optical elements. The optical elements and the sealing layer are provided on the resin film. The functional film is a polarizing film or a cover film and is provided on a surface of the display panel (see PTL 1, for example).

### CITATION LIST

### Patent Literature

PTL 1: JP 2013-109869 A (published Jun. 6, 2013)

### SUMMARY

### Technical Problem

The barrier layer and the sealing layer inhibit moisture and oxygen from infiltrating the optical elements. However, the barrier layer, sealing layer, and optical elements are fragile layers that are vulnerable to external forces. Thus, stress applied to the fragile layers in a case that the display device is folded needs to be minimized.

In the vicinity of the center of the display device in the thickness direction, a neutral surface is provided that does not expand or contract when the display device is folded. Note that the neutral surface is determined on the basis of a layering order, Young's modulus, and the thickness of the layers.

When the display device is folded, tensile stress is applied to layers disposed further to the outer side than the neutral surface in the thickness direction, and compressive stress is applied to layers disposed further to the inner side than the neutral surface in the thickness direction.

The functional film has a much larger thickness than that of the resin film substrate that configures the support body, and is provided only on one side of the display panel. A display device in which the functional film is provided on both sides of the resin film substrate cannot be folded. Meanwhile, in the display device in which the functional film is provided only on one side of the resin film substrate, stress is more likely to be applied to the fragile layers, such as a moisture barrier layer. For example, when the functional film is provided only on one side of the resin film substrate, in a case where the display device is folded with the resin film substrate being disposed on the inner side, the tensile stress is likely to be applied to the barrier layer because the barrier layer is positioned on the outer side of a neutral surface in the thickness direction.

Then, when the barrier layer breaks (a film breakage) as a result of receiving the tensile stress, and the moisture infiltrates, a lighting failure occurs in the optical element.

In light of the above-described issue, an object of the present disclosure is to provide a display device capable of reducing stress acting on a folding portion, stopping a breakage of a layer from occurring in the folding portion due to folding of the display device, and inhibiting a lighting failure, and a production method of the display device.

### Solution to Problem

To solve the above-described issues, a display device according to one aspect of the present disclosure is a display device having at least one folding portion includes: a support body including a barrier layer; a plurality of optical elements provided on the support body; a sealing film sealing the plurality of optical elements and including a plurality of inorganic layers superimposed on each other and at least one organic layer sandwiched between two inorganic layers of the plurality of inorganic layers; an adhesive layer provided on the sealing film; and a cover layer provided on the adhesive layer and including a functional film layer. In a plan view, the adhesive layer and the cover layer are provided avoiding at least a region of the at least one folding portion adjacent to the optical elements.

To solve the above-described issues, in a method for producing a display device according to one aspect of the present disclosure, the display device including: a support body including a barrier layer; a plurality of optical elements provided on the support body; a sealing film sealing the plurality of optical elements and including a plurality of inorganic layers superimposed on each other and at least one organic layer sandwiched between two inorganic layers of the plurality of inorganic layers; an adhesive layer provided on the sealing film; and a cover layer provided on the adhesive layer and including a functional film layer, and further including at least one folding portion, the method includes forming the adhesive layer and the cover layer, in a plan view, while avoiding at least a region of the at least one folding portion adjacent to the optical elements.

### Advantageous Effects of Disclosure

According to one aspect of the present disclosure, a display device and a production method of the display device can be provided, the display device being capable of reducing stress acting on a folding portion, stopping a breakage of a layer from occurring in the folding portion due to folding of the display device, and inhibiting a lighting failure.

### BRIEF DESCRIPTION OF DRAWINGS

FIG. 1 is a cross-sectional view illustrating a schematic configuration of a periphery of a folding portion of a flexible display according to a first embodiment of the present disclosure.

FIG. 2 is a cross-sectional view illustrating a schematic configuration of the flexible display according to the first embodiment of the present disclosure.

FIG. 3 is a plan view illustrating a wiring configuration of the flexible display according to the first embodiment of the present disclosure.

FIG. 4 is a plan view illustrating a schematic configuration of the flexible display according to the first embodiment of the present disclosure.

FIG. 5 is a cross-sectional view illustrating a schematic configuration of a periphery of a terminal portion of the flexible display according to the first embodiment of the present disclosure.

FIGS. 6A to 6C are cross-sectional views illustrating a process for producing main portions of the flexible display according to the first embodiment of the present disclosure in the order of the process.

FIG. 7 is a cross-sectional view illustrating a schematic configuration of the periphery of the folding portion of the flexible display according to a second embodiment of the present disclosure.

FIG. 8 is a cross-sectional view illustrating a schematic configuration of the flexible display according to the second embodiment of the present disclosure.

FIG. 9 is a plan view illustrating a wiring configuration of the flexible display according to the second embodiment of the present disclosure.

FIG. 10 is a plan view illustrating a schematic configuration of the flexible display according to the second embodiment of the present disclosure.

FIG. 11 is a cross-sectional view illustrating a schematic configuration of the periphery of the folding portion of the flexible display according to a third embodiment of the present disclosure.

FIG. 12 is a cross-sectional view illustrating a schematic configuration of the flexible display according to the third embodiment of the present disclosure.

FIG. 13 is a plan view illustrating a schematic configuration of the flexible display according to a fourth embodiment of the present disclosure.

FIG. 14 is a cross-sectional view illustrating a schematic configuration of the periphery of the folding portion of the flexible display according to the fourth embodiment of the present disclosure.

FIG. 15 is a cross-sectional view illustrating a schematic configuration of the periphery of the folding portion of the flexible display according to a fifth embodiment of the present disclosure.

FIG. 16 is a cross-sectional view illustrating an example of a light guide used in the flexible display according to the fifth embodiment of the present disclosure.

FIG. 17 is a cross-sectional view illustrating another example of the light guide used in the flexible display according to the fifth embodiment of the present disclosure.

FIG. 18 is a cross-sectional view illustrating yet another example of the light guide used in the flexible display according to the fifth embodiment of the present disclosure.

### DESCRIPTION OF EMBODIMENTS

A detailed description follows regarding embodiments of the present disclosure.

### First Embodiment

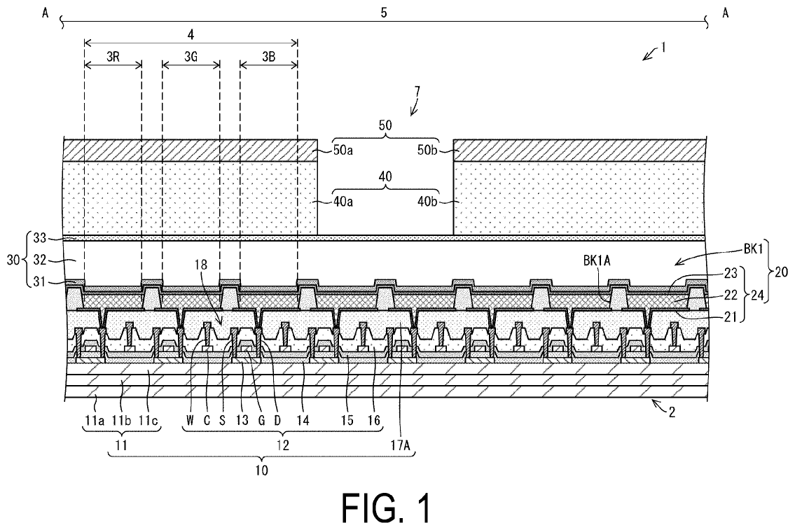

A description follows regarding an embodiment of the present disclosure, with reference to FIG. 1 to FIGS. 6A to 6C.

Note that, in the following description, the description is made taking as an example a case in which a flexible display (display device) according to the present embodiment is an organic EL display device provided with an Organic Light Emitting Diode (OLED) layer including OLED elements, which is referred to as organic EL elements, as light emitting elements (optical elements).

### Schematic Configuration of Flexible Display

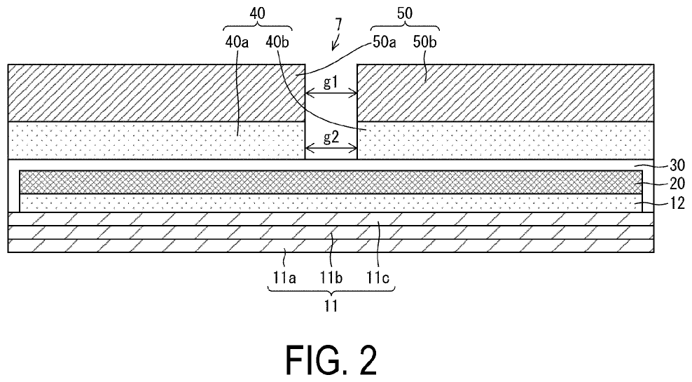

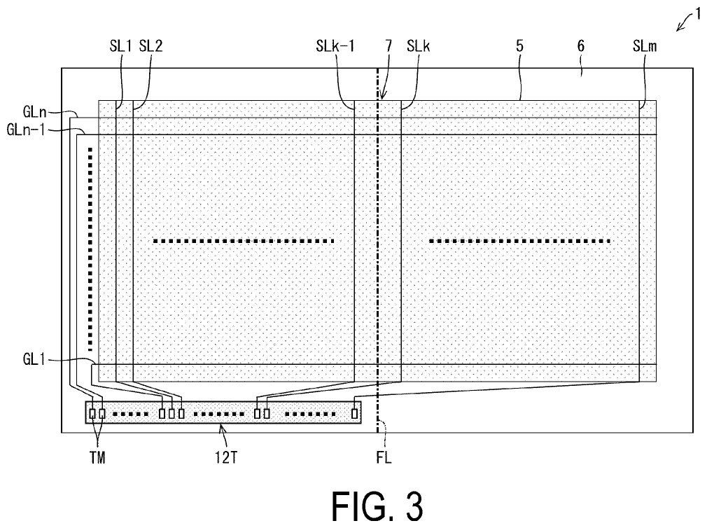

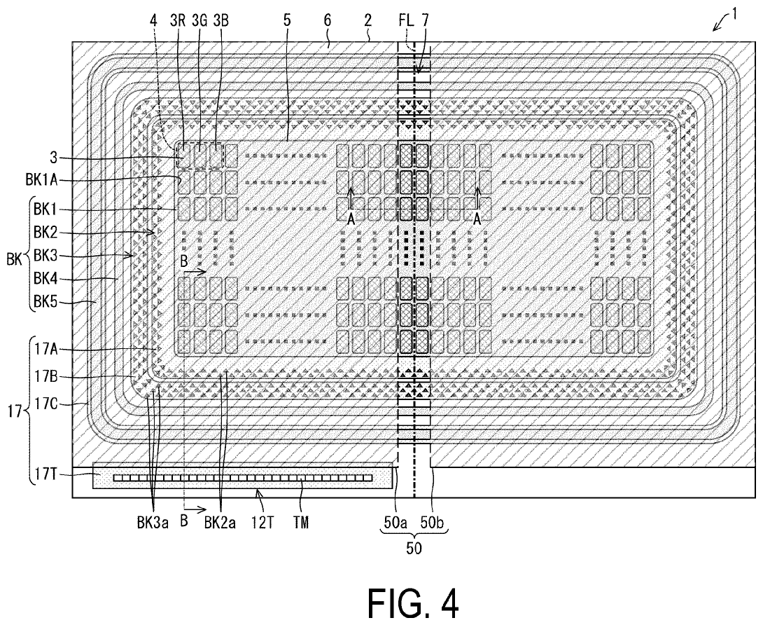

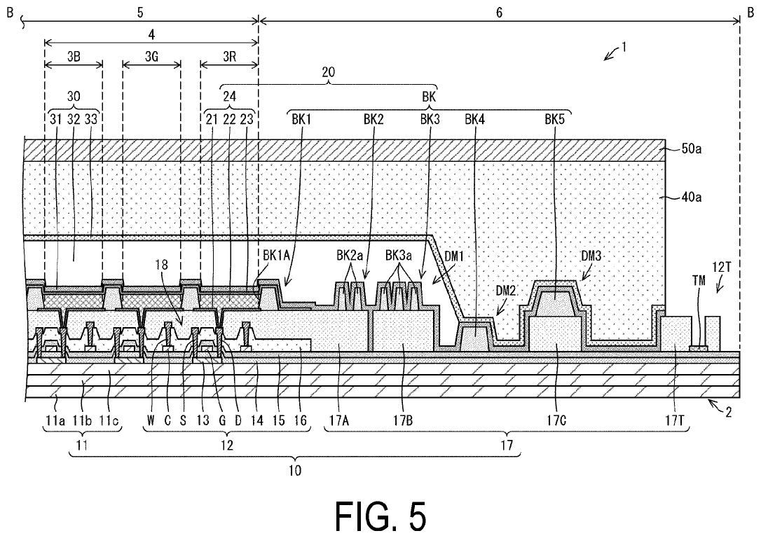

FIG. 1 is a cross-sectional view illustrating a schematic configuration of a periphery of a folding portion of a flexible display 1 according to the present embodiment. FIG. 2 is a cross-sectional view illustrating a schematic configuration of the flexible display 1 according to the present embodiment. FIG. 3 is a plan view illustrating a wiring configuration of the flexible display 1 according to the present embodiment. FIG. 4 is a plan view illustrating a schematic configuration of the flexible display 1 according to the present embodiment. FIG. 5 is a cross-sectional view illustrating a schematic configuration of a periphery of a terminal portion 12T of the flexible display 1 according to the present embodiment.

Note that FIG. 1 corresponds to a cross-sectional view of the flexible display 1 illustrated in FIG. 4 as viewed in the direction of arrows along a line A-A. FIG. 5 corresponds to a cross-sectional view of the flexible display 1 illustrated in FIG. 4 as viewed in the direction of arrows along a line B-B.

The flexible display 1 according to the present embodiment is a foldable flexible image display device (foldable display) that is provided so as to be foldable (bendable) and developable (expandable).

Here, a developed state is a state in which the flexible display 1 is developed to 180 degrees. Specifically, the flexible display 1 is flat as a result of being opened, namely, is in a so-called fully flat state.

In the following description, an example will be described of a case in which the flexible display 1 is a bi-fold rectangular shaped display.

As illustrated in FIG. 1 and FIG. 3 to FIG. 5, in a plan view, the flexible display 1 includes a display region 5 configured to display an image and a frame-shaped frame region 6 that is a peripheral region surrounding a periphery of the display region 5. In FIG. 4, for the convenience of illustration, a ratio of the frame region 6 with respect to the display region 5 is illustrated so as to be much larger than an actual ratio.

As illustrated in FIG. 1, FIG. 2, and FIG. 5, the flexible display 1 according to the present embodiment has a configuration in which an adhesive layer 40 configured by adhesive layers 40a and 40b and a cover layer 50 configured by cover layers 50a and 50b are provided in this order on an OLED panel 2 from the OLED panel 2 side.

As illustrated in FIG. 1 to FIG. 4, the flexible display 1 is provided with a folding portion that includes a groove 7.

As illustrated in FIG. 3 and FIG. 4, the single folding portion (the groove 7) is provided along the lateral direction of the flexible display 1, while linking central portions of sides along the longitudinal direction of the flexible display 1, such that each of the sides along the longitudinal direction of the flexible display 1 is bisected (namely, divided into two equal parts) at a central portion of each of the sides. Note that, in FIG. 3 and FIG. 4, the center of folding of the folding portion is illustrated as a folding line FL, using a dashed line.

The groove 7 is formed as a result of a gap being provided between the adhesive layers 40a and 40b and between the cover layers 50a and 50b.

The OLED panel 2 has a configuration in which an OLED layer 20 that forms organic EL elements 24 (the OLED elements) and a sealing film 30 are provided on a thin film transistor (TFT) substrate 10, in this order from the TFT substrate 10 side. A more detailed description follows.

### TFT Substrate 10

The TFT substrate 10 is provided with an electrically insulating support body 11, and a TFT layer 12 provided on the support body 11.

### Support Body 11

As illustrated in FIG. 1 and FIG. 2, the support body 11 is a flexible layered film provided with a resin layer 11b, a barrier layer 11c (a moisture barrier layer) provided on the resin layer 11b, and a lower face film 11a provided on a surface of the resin layer 11b opposite to the barrier layer 11c interposing an adhesive layer (not illustrated) between the resin layer 11b and the lower face film 11a.

Examples of the resin used for the resin layer 11b include a polyimide, polyethylene, and a polyamide.

The barrier layer 11c is a layer for preventing moisture or impurities from reaching the TFT layer 12 and the OLED layer 20 formed on the support body 11, and can be formed, for example, from a silicon oxide (SiOx) film, a silicon nitride (SiNx) film, a layered film of these, or the like.

The barrier layer 11c is provided across an entire surface of the resin layer 11b, such that the surface of the resin layer 11b is not exposed. In this way, even in a case where a resin that is not resistant to liquid chemicals, such as a polyimide, is used as the resin layer 11b, elution of the resin by liquid chemicals and process contamination can be prevented.

The lower face film 11a adhering to the lower face of the resin layer 11b that has been peeled off from a carrier substrate, such as a glass substrate, used in the production of the OLED panel 2 allows the produced flexible display 1 to have sufficient strength, even when the resin layer 11b is extremely thin. As the lower face film 11a, a plastic film that is made from a flexible resin, such as polyethylene terephthalate, polyethylene naphthalate, a cycloolefin polymer, a polyimide, a polycarbonate, polyethylene, and an aramid, is used, for example.

### TFT Layer 12

As illustrated in FIG. 1 and FIG. 2, the TFT layer 12 includes: a plurality of semiconductor layers 13 that are each formed in an island-shape; a gate insulating film 14 formed on the support body 11 and covering the semiconductor layers 13; a first metal layer including gate electrodes G formed on the gate insulating film 14; an inorganic insulating film 15 (a first passivation film) covering the first metal layer; a second metal layer formed on the inorganic insulating film 15 and including capacity electrodes C; an inorganic insulating film 16 (a second passivation film) formed on the inorganic insulating film 15 and covering the second metal layer; a third metal layer formed on the inorganic insulating film 16 and including source electrodes S, drain electrodes D, and wires W; an organic insulating film 17 including a flattening film; and a terminal portion 12T (FIG.3) in which terminals TM (FIG.3) for the respective wires are provided. Note that an inorganic insulating film (not illustrated) may be provided on the third metal layer as a third passivation film.

The semiconductor layer 13, the gate electrode G, the inorganic insulating films 15 and 16, the source electrode S and the drain electrode D form a TFT 18. Since the configuration of the TFT is known, a detailed description thereof is omitted herein. One of gate lines GL1, GL2 . . . GLn-1, and GLn (where n is any integer, and hereinafter, these gate lines will be collectively referred to as “gate lines GL”) that are formed by the first metal layer is connected to the gate electrode G provided in each of the TFTs 18. One of source lines SL1, SL2 . . . SLm-1, and SLm (where m is any integer, and hereinafter, these source lines will be collectively referred to as “source lines SL”) is connected to the source electrode S provided in each of the TFTs 18. The drain electrodes D are connected to first electrodes 21 via a contact hole penetrating the organic insulating film 17. The gate lines GL and the source lines SL intersect each other while being orthogonal to each other in a plan view.

A region surrounded by the gate lines GL and the source lines SL in a lattice-shape is a sub pixel 3, and a single pixel 4 is formed by a set of three of the sub pixels 3 of each of colors. In an example illustrated in FIG. 1 and FIG. 4, a red sub pixel 3R, a green sub pixel 3G, and a blue sub pixel 3B are provided as the sub pixels 3, and the single pixel 4 is formed by the red sub pixel 3R, the green sub pixel 3G, and the blue sub pixel 3B. The TFT 18 is provided in each of the sub pixels 3.

Note that, in FIG. 1, an example is illustrated of a case in which the TFT 18 has a top gate configuration with the semiconductor layer 13 as a channel, but the TFT 18 may have a bottom gate configuration.

As illustrated in FIG. 3 to FIG. 5, as well as the terminal portion 12T on which the terminals TM for the respective wires including the gate lines GL, the source lines SL, the wires W, and the like are provided, a mounting region for a flexible printed circuit (FPC) substrate (not illustrated) is also provided in a part of the frame region 6 along an edge portion of the OLED panel 2. The terminal portion 12T on which the plurality of terminals TM are provided, and the FPC substrate are bonded using an Anisotropic Conductive Film (ACF) (not illustrated).

The terminal portion 12T is configured such that various signals supplied from a display control circuit (not illustrated) or a reference potential are input via lead-out wires, and this allows drive of the TFT 18 to be controlled. Note that the display control circuit may be mounted on a control substrate connected via the FPC substrate, or may be provided on the FPC substrate. Note that a gate driver and a source driver may be provided on the FPC substrate, and may be provided in the frame region 6 of the OLED panel 2.

As illustrated in FIG. 3, the gate lines GL are formed across the folding portion. As illustrated in FIG. 3, in a plan view, the terminal portion 12T is provided in the frame region 6 between the display region 5 and an edge portion of the TFT substrate 10 (in other words, an edge portion of the OLED panel 2), while not overlapping with the folding portion (groove 7).

The wires including the gate lines GL, the source lines SL, and the wires W, and the TFTs 18 are covered by a part of the organic insulating film 17 that functions as a flattening film.

As illustrated in FIG. 1, FIG. 4, and FIG. 5, the organic insulating film 17 is formed by a plurality of organic insulating film pattern portions provided in the same plane. The organic insulating film 17 includes: a first organic insulating film pattern portion 17A formed extending from the display region 5 to the frame region 6; a second organic insulating film pattern portion 17B formed in a frame-shape in the frame region 6 and surrounding the first organic insulating film pattern portion 17A while being separated from the first organic insulating film pattern portion 17A; a third organic insulating film pattern portion 17C formed in a frame-shape and surrounding the second organic insulating film pattern portion 17B while being separated from the second organic insulating film pattern portion 17B; and a terminal portion organic insulating film pattern portion 17T covering edge portions of the terminals TM.

The first organic insulating film pattern portion 17A covers the inorganic insulating film 16 and the third metal layer formed on the inorganic insulating film 16. As a result, the first organic insulating film pattern portion 17A levels out steps on the TFTs 18 and the third metal layer in the display region 5.

Note that, while the TFTs 18 and the organic EL elements 24 are provided in the first organic insulating film pattern portion 17A, the TFTs 18 and the organic EL elements 24 are not provided in the second organic insulating film pattern portion 17B and the third organic insulating film pattern portion 17C.

Furthermore, openings that cause the terminals TM to be exposed are provided in the terminal portion organic insulating film pattern portion 17T covering the edge portions of the terminals TM.

Portions of the terminals TM that are not covered by the terminal portion organic insulating film pattern portion 17T are electrically connected to a flexible film cable, an FPC substrate, or an external circuit such as an IC, via an ACF or the like.

### OLED Layer 20

As illustrated in FIG. 1, FIG. 4, and FIG. 5, the OLED layer 20 includes: the first electrodes 21 (lower electrodes); an organic EL layer 22 formed on the first electrodes 21 and formed from an organic layer including at least a light-emitting layer; second electrodes 23 (upper electrodes) formed on the organic EL layer 22; and banks BK (walls, banks).

The first electrode 21, the organic EL layer 22, and the second electrode 23 form the organic EL element 24 (the OLED element, the light emitting element) that forms each of the sub pixels 3. Note that, in the present embodiment, the layers between the first electrode 21 and the second electrode 23 are collectively referred to as the organic EL layer 22.

The first electrode 21, the organic EL layer 22, the second electrode 23, and the banks BK are each provided in the same shape on either side of the folding line FL.

Note that an optical adjustment layer (not illustrated) that performs optical adjustment, and a protection layer that protects the second electrode 23 and inhibits oxygen or moisture from infiltrating the organic EL element 24 from outside may be formed on the second electrode 23. In the present embodiment, the organic EL layer 22 formed on each of the sub pixels 3, the pair of electrode layers (the first electrode 21 and the second electrode 23) that sandwich the organic EL layer 22, and the optical adjustment layer and the protection layer (not illustrated) that are formed as necessary, are referred to together as the organic EL element 24.

The first electrode 21 is formed on the first organic insulating film pattern portion 17A in the display region 5. The first electrode 21 allows holes to be injected (supplied) into the organic EL layer 22, and the second electrode 23 allows electrons to be injected into the organic EL layer 22. The holes and the electrons injected into the organic EL layer 22 are recombined in the organic EL layer 22, and thus form excitons. The formed excitons emit light as they become deactivated from an excited state to a ground state, and the emitted light is emitted to the outside from the organic EL element 24.

The first electrode 21 is electrically connected to the TFT 18 via a contact hole formed in the organic insulating film 17.

The first electrode 21 is a pattern electrode patterned in an island-shape for each of the sub pixels 3, and is formed in a matrix shape, for example, on the first organic insulating film pattern portion 17A, which is the flattening film. Meanwhile, the second electrode 23 is a solid-like common electrode provided in common to each of the sub pixels 3, for example, and is formed across the folding portion. However, the present embodiment is not limited to this example, and the second electrode 23 may be a pattern electrode formed in an island-shape for each of the sub pixels 3, and each of the second electrodes 23 patterned in the island-shape may be configured to be connected with each other by auxiliary wiring and the like (not illustrated).

Note that, although not illustrated, a second electrode connecting portion, in which a second electrode connection electrode (not illustrated) connected to the second electrode 23 is provided, is provided on the outer side of the display region 5, more specifically, on the outer side of one pair of sides of the display region 5, among two pairs of sides of the display region 5, along the sides that face each other.

The banks BK are provided with a bank BK1 disposed inside the display region 5, and banks BK2 to BK5 disposed in the frame region 6.

The bank BK1 is formed on the organic insulating film 17 in the display region 5 (specifically, on the first organic insulating film pattern portion 17A in the display region 5).

The bank BK1 is provided in a lattice-shape in a plan view, for example, while covering peripheral portions (namely, each of the edges) of the first electrode 21. The bank BK1 functions as an edge cover that inhibits, at the peripheral portions of the first electrode 21, a short circuit with the second electrode 23 due to electrode concentration or thinning of the organic EL layer 22, and also functions as a sub pixel isolation layer that isolates the sub pixels 3 such that electric current does not leak to the adjacent sub pixel 3.

In the bank BK1, an opening BK1A is provided for each of the sub pixels 3. An exposed portion of the first electrode 21, which is exposed in the opening BK1A, forms a light emitting region of each of the sub pixels 3.

When selective coating is performed such that the organic EL layer 22 of the organic EL elements 24 emits a different color light for each of the sub pixels 3, as illustrated in FIG. 1, FIG. 2, and FIG. 4, the organic EL layer 22 is formed for each of the regions (the sub pixels 3) surrounded by the bank BK1.

For example, the organic EL layer 22 is formed by layering a hole injecting layer, a hole transport layer, a light emitting layer, an electron transport layer, and an electron injecting layer, in this order from the first electrode 21 side. Note that one layer may have a plurality of functions. Furthermore, a carrier blocking layer may be provided between the layers as appropriate.

Note that the above-described layering order is for a case in which the first electrode 21 is the positive electrode and the second electrode 23 is the negative electrode, and when the first electrode 21 is the negative electrode and the second electrode 23 is the positive electrode, the order of each of the layers forming the organic EL layer 22 is reversed.

When the flexible display 1 is the bottom-emitting type that emits the light from a back surface side of the support body 11, it is preferable that the second electrode 23 be formed by a reflective electrode, and the first electrode 21 be formed by a transparent electrode, such as indium tin oxide (ITO), or by a semi-transparent light-transmissive electrode formed from a thin film of a metal such as gold (Au).

Meanwhile, when the flexible display 1 is the top-emitting type that emits the light from the sealing film 30 side, it is preferable that the first electrode 21 be formed by a reflective electrode material, and the second electrode 23 be formed by a transparent or semi-transparent light-transmissive electrode material.

The first electrode 21 and the second electrode 23 may each have a single layer structure or may each have a layered structure. For example, when the organic EL element 24 is a top-emitting organic EL element, the first electrode 21 may have a layered structure configured by a reflective electrode and a transparent electrode.

The bank BK2 is formed in a frame-shape on the first organic insulating film pattern portion 17A of the frame region 6 while surrounding the display region 5. In other words, the lattice-shaped bank BK1 and the frame-shaped bank BK2 that is formed on the outer side of the lattice-shaped bank BK1 while surrounding the lattice-shaped bank BK1, are provided on the first organic insulating film pattern portion 17A.

As illustrated in FIG. 4 and FIG. 5, the bank BK2 has a configuration in which a plurality of dot-shaped banks BK2a, which are separated from each other, are arranged in a plurality of rows and each form an intermittent frame-shape, and the adjacent rows of dot-shaped banks BK2a are regularly arranged in a zig-zag shape with respect to each other.

The bank BK3 is formed in a frame-shape on the second organic insulating film pattern portion 17B while surrounding the bank BK2.

As illustrated in FIG. 4 and FIG. 5, the bank BK3 has a configuration in which a plurality of dot-shaped banks BK3a, which are separated from each other, are arranged in a plurality of rows and each form an intermittent frame-shape, and the adjacent rows of dot-shaped banks BK3a are regularly arranged, in a plan view, in a zig-zag shape with respect to each other.

The banks BK2 and BK3 function as spacers that support masks, which are used for film formation of the organic EL layer 22 and the like, while keeping the masks separated from a target film forming substrate, so that the masks do not come into contact with a surface of the target film forming substrate on which the film formation is performed.

Furthermore, during film formation of an organic layer 32 of the sealing film 30, the banks BK2 and BK3 gradually reduce a flow velocity of a liquid organic insulating material (ink), which is the material of the organic layer 32, and regulate wet spreading of the organic insulating material.

Particularly, when the dot-shaped banks BK2a and BK3a are used as the banks BK2 and BK3, after the liquid organic material used for the organic layer 32 is applied using an ink-jet method and the like, the dot-shaped banks BK2a and BK3a align edges of the wetly spreading liquid organic material, inhibit a flow of the wetly spreading liquid organic material, and align edge portions of the wetly spreading liquid organic material to be in a substantially straight-line shape.

By the liquid organic material passing the banks BK2 and BK3 and wetly spreading, the banks BK2 and BK3 function as resistance. Thus, by the liquid organic material passing the banks BK2 and BK3, the speed of the wet spreading decreases. According to the present embodiment, in this way, by providing the banks BK2 and BK3 further to the display region 5 side than the bank BK4, the flow of the liquid organic material can be reduced.

Furthermore, since the second organic insulating film pattern portion 17B is separated from the first organic insulating film pattern portion 17A, the second organic insulating film pattern portion 17B, on which the bank BK3 provided, is used as a first dam portion DM1 to inhibit moisture from infiltrating the TFTs 18 and the organic EL elements 24 inside the first organic insulating film pattern portion 17A. In this way, by dividing the organic insulating film 17 and blocking the pathway for the penetration of moisture, reliability of the flexible display 1 can be improved.

Furthermore, although not illustrated, in the present embodiment, the second electrode 23 is formed while covering the bank BK2 that is formed along a side of the first organic insulating film pattern portion 17A along which the second electrode connecting portion is provided.

Thus, as a result of the bank BK2 being formed by the plurality of dot-shaped banks BK2a, the second electrode 23 is formed while overlapping with the steps of the dot-shaped banks BK2a, and is also formed on planar portions that are gaps between the dot-shaped banks BK2a. In this way, as a result of the bank BK2 being formed by the plurality of dot-shaped banks BK2a, the second electrode 23 and the second electrode connecting portion can be reliably connected to each other in an electrically conductive manner.

Note that, in FIG. 4 and FIG. 5, an example is illustrated of a case in which the bank BK2 is a double frame-shaped bank that is configured by two rows of the dot-shaped banks BK2a each arranged in an intermittent frame-shape, and the bank BK3 is a triple frame-shaped bank that is configured by three rows of the dot-shaped banks BK3a each arranged in an intermittent frame-shape. However, it is sufficient that the dot-shaped banks BK2a and BK3a be each formed in a double frame-shape or a multiple frame-shape with a greater number than the double frame-shape.

Furthermore, in FIG. 4, an example is illustrated of a case in which the dot-shaped banks BK2a and BK3a are each formed in triangular shapes in a plan view. However, the present embodiment is not limited to this example, and the dot-shaped banks BK2a and BK3a may each have circular hemispherical or cylindrical planar shapes, or may each have oval semi-elliptic spherical or elliptic cylindrical planar shapes. Furthermore, the dot-shaped banks BK2a and BK3a may each have rectangular square columnar planar shapes.

Furthermore, the banks BK2 and BK3 may be each formed in a continuous line-shape. In this case, each of the bank BK2 and the bank BK3 need not necessarily be formed in the multiple frame-shape.

The bank BK4 is formed on the inorganic insulating film 15 in the frame region 6. The bank BK4 is an organic layer stopper (a first organic layer stopper, a main organic layer stopper) that defines the edges of the organic layer 32 by holding back the liquid organic material used for the organic layer 32 (in other words, by holding back the organic layer 32). The bank BK4 is formed, not in a dot-shape, but in a frame-shape formed by a continuous line on the outer side of the second organic insulating film pattern portion 17B, while surrounding the first organic insulating film pattern portion 17A provided in the display region 5 and the second organic insulating film pattern portion 17B.

Since the bank BK4 is separated from the first organic insulating film pattern portion 17A and the second organic insulating film pattern portion 17B, the bank BK4 is used as a second dam portion DM2 to inhibit moisture from infiltrating the TFTs 18 and the organic EL elements 24 inside the first organic insulating film pattern portion 17A.

The bank BK5 is a backup organic layer stopper (a second organic layer stopper, a backup organic layer stopper) that holds back the organic layer 32. The bank BK5 is provided on the third organic insulating film pattern portion 17C that is formed in a frame shape and provided in the frame region 6, such that the height of the upper face (top face) of the bank BK5 becomes higher than the height of the upper face (top face) of the bank BK4.

The third organic insulating film pattern portion 17C, on which the bank BK5 is provided, holds back the organic insulating material that forms the organic layer 32, when the bank BK4 cannot hold back the organic layer 32. Furthermore, since the third organic insulating film pattern portion 17C is separated from the first organic insulating film pattern portion 17A, the bank BK4, and the second organic insulating film pattern portion 17B, the third organic insulating film pattern portion 17C is used as a third dam portion DM3 to inhibit moisture from infiltrating the TFTs 18 and the organic EL elements 24 inside the first organic insulating film pattern portion 17A.

The bank BK5 is provided on the third organic insulating film pattern portion 17C along the third organic insulating film pattern portion 17C. As a result, on the outer side of the frame-shaped bank BK4, the bank BK5 is formed in a frame-shape formed by a continuous line of a constant width while surrounding the bank BK4.

In this way, the banks BK4 and BK5 are the organic layer stoppers for holding back the organic layer 32, and the edges of the organic layer 32 are overlapped with one of the banks BK4 and BK5 (preferably with the bank BK4). In an example illustrated in FIG. 4 and FIG. 5, the edges of the organic layer 32 are overlapped with the upper face (top face) of the bank BK4. Thus, the organic layer 32 is not present on the outer side of the frame-shaped bank BK4.

As described above, in the present embodiment, in a plan view, the frame-shaped bank BK2, the frame-shaped bank BK3, the frame-shaped bank BK4, and the frame-shaped bank BK5 are provided in this order from the inner side toward the outer side around the lattice-shaped bank BK1, on the outer side of the lattice-shaped BK1 that is provided across the folding portion (folding line FL). Note that, here, the lattice-shaped bank BK1 can be interpreted to mean the display region 5 or a group of the organic EL elements 24.

The banks BK1 to BK5 are formed by an organic insulating material. The banks BK1 to BK5 are formed from a photosensitive resin such as an acrylic resin or a polyimide resin, for example. The banks BK1 to BK5 can be formed in the same process, for example.

### Sealing Film 30

The sealing film 30 includes: a first inorganic layer 31 (a lower inorganic sealing layer, a first inorganic sealing layer); the organic layer 32 (the organic sealing layer); and a second inorganic layer 33 (an upper inorganic sealing layer, a second inorganic sealing layer) that are layered in this order from the TFT substrate 10 side.

The first inorganic layer 31 and the second inorganic layer 33 have a moisture-proof function to inhibit the infiltration of moisture, and function as barrier layers to inhibit deterioration of the organic EL elements 24 caused by moisture or oxygen.

The organic layer 32 is used as a buffer layer (a stress relief layer), which relieves stress in the first inorganic layer 31 and the second inorganic layer 33 in which film stress is large. Step portions and foreign material on the surface of the OLED layer 20 in the display region 5 are buried with the organic layer 32, forming the leveled film, and pinholes are also filled with the organic layer 32. Furthermore, the organic layer 32 prevents the occurrence of cracks in the second inorganic layer 33 when the second inorganic layer 33 is layered, by leveling an underlayer of the second inorganic layer 33.

The first inorganic layer 31 and the second inorganic layer 33 can be each formed by a silicon oxide film, a silicon nitride film, or a silicon oxynitride film, or by a layered film of these films, formed using CVD, for example.

The organic layer 32 is thicker than the first inorganic layer 31 and the second inorganic layer 33, and is a light-transmissive organic insulating film. The organic layer 32 is formed, for example, by applying a liquid organic material on the first inorganic layer 31 in the display region 5 using an ink-jet method, and curing the liquid organic material. Examples of the organic material include a photosensitive resin such as an acrylic resin, an epoxy resin, and a silicon resin. The organic layer 32 can be formed, for example, by performing ink-jet application of an ink including this type of photosensitive resin as the liquid organic material onto the first organic layer 31, and then performing ultraviolet (UV) curing.

The first inorganic layer 31 is formed above the support body 11 over the entire surface of the display region 5 and the frame region 6 excluding the surface over the terminals TM, while covering the second electrode 23 and the organic insulating film 17 excluding a part of the terminal portion 12T (more specifically, the first organic insulating film pattern portion 17A, the second organic insulating film pattern portion 17B, the third organic insulating film pattern portion 17C, and an edge portion of the terminal portion organic insulating film pattern portion 17T on the third organic insulating film pattern portion 17C side) in a plan view.

The organic layer 32 covers the first organic insulating film pattern portion 17A, the second organic insulating film pattern portion 17B, the organic EL elements 24, and the banks BK1 to BK3, with the first inorganic layer 31 interposed therebetween, and also covers an end face of the bank BK4 on the bank BK3 side, and a part of the upper face of the bank BK4. The organic layer 32 is provided in the region surrounded by the bank BK4.

The second inorganic layer 33 is formed while superimposed on the first inorganic layer 31. The first inorganic layer 31 and the second inorganic layer 33 are formed while sandwiching the organic layer 32 therebetween, so that the organic layer 32 is not exposed to the outside.

The second inorganic layer 33 covers the organic insulating film 17 excluding a part of the terminal portion 12T (more specifically, the first organic insulating film pattern portion 17A, the second organic insulating film pattern portion 17B, the third organic insulating film pattern portion 17C, and the edge portion of the terminal portion organic insulating film pattern portion 17T on the third organic insulating film pattern portion 17C side), the organic EL elements 24, and the banks BK1 to BK5 via at least the first inorganic layer 31 among the first inorganic layer 31 and the organic layer 32.

### Adhesive Layers 40a and 40b, and Cover Layers 50a and 50b

In the present embodiment, as illustrated in FIG. 1, FIG. 2, and FIG. 4, the adhesive layer 40 is divided into the adhesive layer 40a and the adhesive layer 40b, and the cover layer 50 is divided into the cover layer 50a and the cover layer 50b.

The cover layer 50a is provided above the sealing film 30, with the adhesive layer 40a interposed therebetween. The cover layer 50b is provided above the sealing film 30, with the adhesive layer 40b interposed therebetween.

The adhesive layer 40a and the adhesive layer 40b are each provided in an island shape and separated from each other at the central portion of each of the sides along the longitudinal direction of the flexible display 1, such that respective end faces of the adhesive layers 40a and 40b face each other along the lateral direction.

Similarly, the cover layers 50a and 50b are each provided in an island shape and separated from each other at the central portion of each of the sides along the longitudinal direction of the flexible display 1, such that respective end faces of the cover layers 50a and 50b face each other along the lateral direction.

Thus, in the flexible display 1, the groove 7 is formed whose inner walls are formed by respective end faces of a layered body formed by the adhesive layer 40a and the cover layer 50a and of a layered body formed by the adhesive layer 40b and the cover layer 50b, with a bottom wall of the groove 7 being the sealing film 30 that is an underlayer on which those layered bodies are layered.

A region of the groove 7 in which the adhesive layers 40a and 40b and the cover layers 50a and 50b are not formed is thinner than the region in which the adhesive layers 40a and 40b and the cover layers 50a and 50b are layered, and is used as the folding portion.

Here, when a gap, in a plan view, between the adhesive layer 40a and the adhesive layer 40b that are adjacent to each other with the folding portion (folding line FL) disposed therebetween is gl, and a gap, in a plan view, between the cover layer 50a and the cover layer 50b that are adjacent to each other with the folding portion (folding line FL) disposed therebetween is g2, g1 and g2 may be the same, as illustrated in FIG. 1 and FIG. 2, or may be different from each other.

Note that it is sufficient that g1 and g2 be set as appropriate in accordance with the curvature of the flexible display 1, and g1 and g2 are not particularly limited to a specific value. As an example, when the thickness of the adhesive layers 40a and 40b is 20 μm and the thickness of the cover layers 50a and 50b is 50 μm, it is preferable that g1 and g2 each be set to 200 μm or greater.

As illustrated in FIG. 2 and FIG. 4, the adhesive layers 40a and 40b and the cover layers 50a and 50b are layered on the sealing film 30, while at least the display region 5, excluding the folding portion, is covered on the OLED panel 2 and also the terminals TM are exposed. In other words, the adhesive layers 40a and 40b and the cover layers 50a and 50b are provided avoiding the folding portion and the terminals TM.

Examples of an adhesive used for the adhesive layers 40a and 40b include an acrylic-based, a silicon-based, and a urethane-based adhesive. Note that the adhesive layers 40a and 40b may be adhesive layers that are formed from a peelable adhesive or from a curing and fix-type adhesive.

Each of the cover layers 50a and 50b is a functional layer having at least one of a protective function, an optical compensation function, or a touch sensor function.

Each of the cover layers 50a and 50b may be a functional film layer formed of a functional film, and also be: a cover film such as a protective film that functions as a support body at a time of the carrier substrate, such as a glass substrate or the like, being peeled off; a hard coat layer such as a hard coat layer including a hard coat film; a polarizing film; a touch sensor film; or the like, for example.

### Production Method of Flexible Display 1

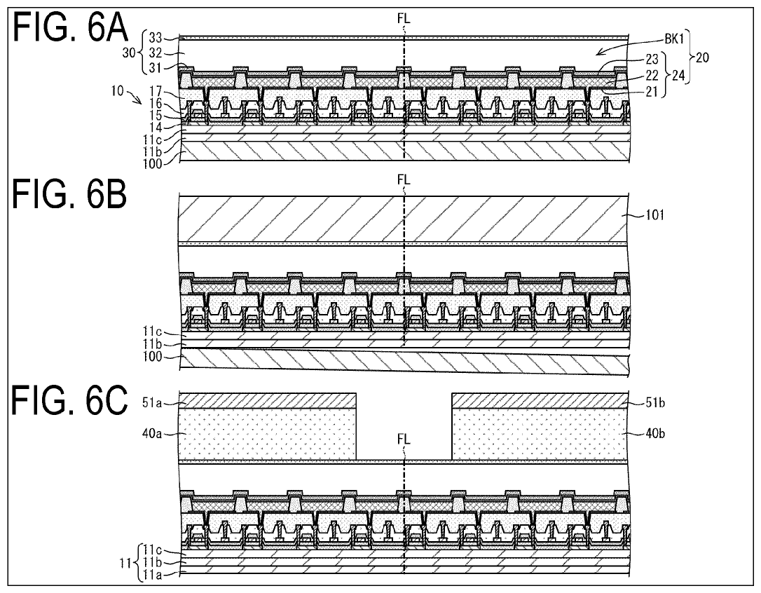

Next, a production method of the flexible display 1 will be described below, mainly with reference to FIG. 1, FIG. 4, FIG. 5, and FIGS. 6A to 6C.

FIGS. 6A to 6C are cross-sectional views illustrating a production process of main portions of the flexible display 1 according to the present embodiment in the order of the process.

First, as illustrated in FIG. 1, FIG. 4, FIG. 5, and FIG. 6A, the resin layer 11b is formed on a carrier substrate 100, such as a glass substrate, and the barrier layer 11c is formed as a film on the resin layer 11b.

The resin layer 11b is formed, for example, by dissolving and thus liquefying the above-described resin or a precursor of the resin in a solvent, applying the liquefied resin or precursor onto the carrier substrate 100 using a slit coating or spin coating method and curing the resin or precursor. The thickness of the resin layer 11b is from 2 to 20 μm, for example.

The barrier layer 11c is formed by the inorganic insulating film, for example, and can be formed by CVD. The thickness of the barrier layer 11c is from 50 to 1500 nm, for example.

Next, using a known method (a known TFT process), the semiconductor layer 13, the gate insulating film 14 formed on the support body 11 while covering the semiconductor layer 13, the first metal layer formed on the gate insulating film 14 and including the gate electrodes G, the inorganic insulating film 15 covering the first metal layer, the second metal layer formed on the inorganic insulating film 15 and including the capacity electrodes C, the inorganic insulating film 16 formed on the inorganic insulating film 15 while covering the second metal layer, the third metal layer formed on the inorganic insulating film 16 and including the source electrodes S, the drain electrodes D, and the wires W, and the terminal portion 12T including the terminals TM are formed on the barrier layer 11c.

Amorphous silicon, low-temperature polysilicon (LTPS), or an oxide semiconductor is used as the semiconductor layer 13, for example. Silicon oxide (SiOx) or silicon nitride (SiNx), or a layered film of silicon oxide and silicon nitride, is used as the gate insulating film 14, for example. The gate insulating film 14 is formed to have a thickness of 400 nm, for example.

For the first metal layer including the gate electrodes G, the second metal layer including the capacity electrodes C, the third metal layer including the source electrodes S, the drain electrodes D, and the wires W, and the terminals TM, for example, a single layer of a metal such as aluminum (Al), tungsten (W) molybdenum (Mo), tantalum (Ta), chromium (Cr), titanium (Ti), or copper (Cu), or a layered film of these, is used. These metal layers are formed to have a thickness of from 1 μm to 30 μm, for example.

Silicon oxide (SiOx) or silicon nitride (SiNx) is used as the inorganic insulating films 15 and 16, for example. The inorganic insulating films 15 and 16 are formed to have a thickness of 300 nm, for example.

Next, a photosensitive resin, such as an acrylic resin or a polyimide resin, is applied so as to cover the third metal layer, and patterning is performed by photolithography or the like, thus forming the organic insulating film 17 by the known method (the known TFT process). At that time, in the present embodiment, the organic insulating film 17 including the first organic insulating film pattern portion 17A, the second organic insulating film pattern portion 17B, the third organic insulating film pattern portion 17C, and the terminal portion organic insulating film pattern portion 17T is formed as the organic insulating film 17. Note that, as long as the organic insulating film 17 can compensate for steps caused by the TFTs 18, the thickness of the organic insulating film 17 is not particularly limited to a specific value, and is from 1 to 3 μm, for example. The first organic insulating film pattern portion 17A, the second organic insulating film pattern portion 17B, the third organic insulating film pattern portion 17C, and the terminal portion organic insulating film 17T are separated from the folding portion with the folding portion interposed therebetween. Furthermore, the first organic insulating film pattern portion 17A, the second organic insulating film pattern portion 17B, the third organic insulating film pattern portion 17C are provided from the inner side toward the outer side around the first organic insulating film pattern portion 17A, such that the second organic insulating film pattern portion 17B and the third organic insulating film pattern portion 17C surround the first organic insulating film pattern portion 17A in a frame shape. In this way, the TFT substrate 10 is formed.

Next, the known method (the known TFT process), such as a sputtering method, is used to pattern form the first electrode 21 in a matrix shape. At this time, the first electrode 21 is electrically connected to the drain electrodes D via a contact hole formed in the organic insulating film 17. The first electrode 21 is formed as a film of a thickness of 100 nm, for example.

Next, an organic film (not illustrated) that is formed, for example, by a positive-working photosensitive resin such as an acrylic resin or a polyimide resin, is formed so as to cover the first electrode 21, the organic insulating film 17, and the inorganic insulating films 15 and 16.

Next, the banks BK1 to BK5 formed by the organic film are pattern formed by photolithography or the like. The banks BK1 to BK5 can be pattern formed using the same material in the same process, using a mask. However, the banks BK1 to BK5 may be formed in separate processes using mutually different masks and materials. The banks BK1 to BK5 are formed to have a height of from 2 μm to 5 μm, for example.

After that, selective coating vapor deposition each corresponding to the sub pixel 3R, 3G, and 3B is performed on the organic EL layer 22, such that light-emitting layers of each color cover the region surrounded by the bank BK1 (namely, the opening BK1A). Note that in the film formation of the organic EL layer 22, a method other than the vapor deposition method may be used, such as a coating method, the ink-jet method, or a printing method.

To perform a full color display, as an example, the light-emitting layer can be pattern formed by performing the selective coating vapor deposition for each of luminescent colors, as described above. However, the present embodiment is not limited to this example, and to perform the full color display, a method may also be used in which luminescent colors for each of the sub pixels 3 are selected by combining the white light-emitting organic EL element 24, which uses a light-emitting layer whose luminescent color is a white (W) color, with a color filter (CF) layer (not illustrated). Furthermore, a method may be adopted in which a full color image display is realized by using the light-emitting layer whose luminescent color is the W color and using a micro cavity structure to each of the sub pixels 3. Note that, when the luminescent colors of each of the sub pixels 3 are changed by using a method such as the CF layer and the micro cavity structure, there is no need for the selective coating of the light-emitting layer for each of the sub pixels 3. The organic EL layer 22 is formed to be a film having a thickness of 250 nm or less, for example.

Next, the second electrode 23 is pattern formed by a vapor deposition method using a mask for vapor deposition, for example, over the entire surface of the display region 5 of the TFT substrate 10 so as to cover the organic EL layer 22 and the banks BK1 and BK2 and be electrically connected to a second electrode connecting electrode of the second electrode connecting portion, and so as to expose a remaining are of the TFT substrate 10. The second electrode 23 is formed to have a thickness of 25 nm, for example.

In this way, the organic EL element 24 formed by the first electrode 21, the organic EL layer 22, and the second electrode 23 can be formed on the TFT substrate 10.

Next, the sealing film 30 is formed on the TFT substrate 10 on which the organic EL elements 24 have been formed. Specifically, first, on the TFT substrate 10 on which the organic EL elements 24 have been formed, the first inorganic layer 31 that is formed from the silicon nitride, the silicon oxide or the like is formed by CVD or the like over the entire surface of the display region 5 and the frame region 6 excluding the surface over the terminals TM, so as to cover the second electrode 23, the organic insulating film 17 excluding a part of the terminal portion 12T, the inorganic insulating film 15, and the banks BK that are not covered by the second electrode 23 (a part of the bank BK2, and the banks BK3 to BK5) in a plan view. The thickness of the first inorganic layer 31 is from 500 to 1500 nm, for example.

Next, the liquid organic material (ink, for example) including the photosensitive resin is applied on the entire surface of the display region 5 using the ink-jet method and the like, for example. The liquid organic material is held back by the bank BK4 that is the organic layer stopper, for example.

Next, the liquid organic insulating material that wetly spreads inside the region surrounded by the bank BK4 is cured. In this way, the organic layer 32 is formed with a uniform film thickness of the edge portion along the bank BK4. The thickness of the organic layer 32 is from 4 to 12 μm, for example.

After that, an inorganic insulating film that is formed from the silicon nitride or the silicon oxide is formed by CVD or the like on the organic layer 32 and the first inorganic layer 31, thus forming the second inorganic layer 33 over the entire surface of the display region 5 and the frame region 6 excluding the surface over the terminals TM. The thickness of the second inorganic layer 33 is from 500 to 1500 nm, for example. In this way, the sealing film 30 configured by the first inorganic layer 31, the organic layer 32, and the second inorganic layer 33 is formed.

After that, a temporarily attached film 101, which has a weak adhesive force and on which an adhesive (not illustrated) is provided, is bonded to the sealing film 30. The temporarily attached film 101 functions as a support body when the resin layer 11b, on which the barrier layer 11c, the TFT layer 12, the OLED layer 20, and the sealing film 30 are layered, is peeled from the carrier substrate 100.

Next, as a result of causing ablation by irradiating, with a laser beam, an interface between the carrier substrate 100 and the resin layer 11b from the reverse face side of the carrier substrate 100 (namely, a face opposite to the face on which the TFT layer 12 is formed), the carrier substrate 100 is peeled off at the interface, as illustrated in FIG. 6B. After that, as illustrated in FIG. 1, FIG. 4, FIG. 5, and FIG. 6A, as the lower face film 11a, a transparent plastic film, for example, is bonded to a peeling face of the resin layer 11b from which the carrier substrate 100 has been peeled.

Note that, in the above-described TFT processes, when a mother substrate formed from a large glass substrate or the like is used as the carrier substrate 100, after the above-described processes, the OLED panel 2 is diced into individual pieces by cutting the obtained layered body. Note that, for the cutting, a laser, a metal blade or the like can be used.

After that, the temporarily attached film 101 is peeled off, and, as illustrated in FIG. 6C, a protective film 51a on which the adhesive layer 40a is provided and a protective film 51b on which the adhesive layer 40b is provided, for example, are bonded onto the sealing film 30. As a result, the protective films 51a and 51b, for example, are bonded onto the sealing film 30 as the cover layers 50a and 50b with the adhesive layers 40a and 40b interposed therebetween. At that time, the cover layers 50a and 50b may be functional films such as a polarizing film and a touch sensor film. In this way, the flexible display 1 according to the present embodiment is produced.

Note that the thickness of the adhesive layer is from 15 to 100 μm, for example. The thickness of the cover layers 50a and 50b differs depending on the type of cover layers 50a and 50b. When the cover layers 50a and 50b are configured by the polarizing film and the touch sensor film, for example, the thickness thereof is from 50 to 150 μm, and when the cover layers 50a and 50b are the protective films 51a and 51b, the thickness thereof may be thinner than the above values.

### Advantageous Effects

As described above, in the flexible display 1, the adhesive layers 40a and 40b and the cover layers 50a and 50b are not provided, and the groove 7 which is the extremely thin folding portion is formed as the folding portion. As a result, the flexible display 1 can be easily folded at the groove 7.

Furthermore, since the adhesive layers 40a and 40b and the cover layers 50a and 50b are provided avoiding the folding portion, compared with a case in which the adhesive layers 40a and 40b and the cover layers 50a and 50b are provided in the folding portion, the barrier layer 11c and the organic EL elements 24 can be positioned closer to the neutral plane in the thickness direction, and since the thickness of the folding portion is thin, the stress acting on the sealing film 30 as well as on the barrier layer 11c and organic EL elements 24 can be reduced.

Thus, according to the flexible display 1 of the present embodiment, a moisture-proof performance is obtained by layering the barrier layer 11c and the sealing film 30, and at the same time, almost no tensile stress is applied to the barrier layer 11c even when the flexible display 1 is folded. Thus, according to the flexible display 1, when the flexible display 1 is folded, a film breakage of the barrier layer 11c and the like does not occur in the folding portion, and thus, a lighting failure of the organic EL element 24 can be inhibited.

Thus, according to the present embodiment, the flexible display 1, which can achieve both flexibility and reliability in a compatible manner, and the production method of the flexible display 1 can be provided.

### First Modified Example

In the present embodiment, as illustrated in FIG. 3 and FIG. 4, the flexible display 1 is the bi-fold rectangular shaped display, and the example is given of the case in which the adhesive layers 40a and 40b and the cover layers 50a and 50b are divided into two by the groove 7 that functions as the folding portion. However, the present embodiment is not limited to this example.

With respect to the flexible display 1, two of the folding portions each configured by the groove 7 may be provided along the lateral direction of the flexible display 1 and divide each side in the longitudinal direction into three equal parts, and the flexible display 1 may be a tri-fold display device whose display region 5 is divided into three parts by the grooves 7. Furthermore, the flexible display 1 may be a multi-fold display device that has four or more folds.

### Second Modified Example

Furthermore, as described above, in the present embodiment, as the example of the display device according to the present embodiment, the flexible display 1 that includes the organic EL elements 24 (the OLED elements) as the light emitting elements is described as the example. However, the flexible display 1 according to the present embodiment is not particularly limited to a flexible display including the organic EL elements, as long as it is a flexible display panel (display device) provided with bendable optical elements. The optical element can include, for example, an electro-optical element in which luminance and transmittance are controlled by an electric current, or an electro-optical element in which luminance and transmittance are controlled by a voltage can be used.

The display panel (display device) provided with the electro-optical elements controlled by the electric current can include, for example, an Electro Luminescence (EL) display provided with Organic Light Emitting Diode (OLED) elements, an EL display such as an inorganic display provided with inorganic light emitting diode elements (inorganic EL elements), or a QLED display provided with Quantum-Dot Light Emitting Diode (QLED) elements. Furthermore, examples of the electro-optical element controlled by a voltage include a liquid crystal display element.

### Third Modified Example

Furthermore, in the present embodiment, the example is given of the case in which the sealing film 30 is formed by the first inorganic layer 31 (the inorganic sealing layer), the second inorganic layer 33 (the inorganic sealing layer), and the organic layer 32 (the organic sealing layer) provided between the first inorganic layer 31 and second inorganic layer 33.

However, the present embodiment is not limited to this example. The sealing film 30 may include a plurality of inorganic layers (inorganic sealing layers), which include three or more inorganic layers and are superimposed on each other, and a plurality of organic layers (organic sealing layers) each sandwiched between the respective inorganic layers.

Therefore, in the present embodiment and in each of embodiments described below, the first inorganic layer 31 and the second inorganic layer 33 can be interpreted to mean the plurality of inorganic layers (inorganic sealing layers) superimposed on each other. Furthermore, the organic layer 32 can be interpreted to mean the at least one layer of the organic layer (organic sealing layer) sandwiched between the plurality of inorganic sealing layers.

### Second Embodiment

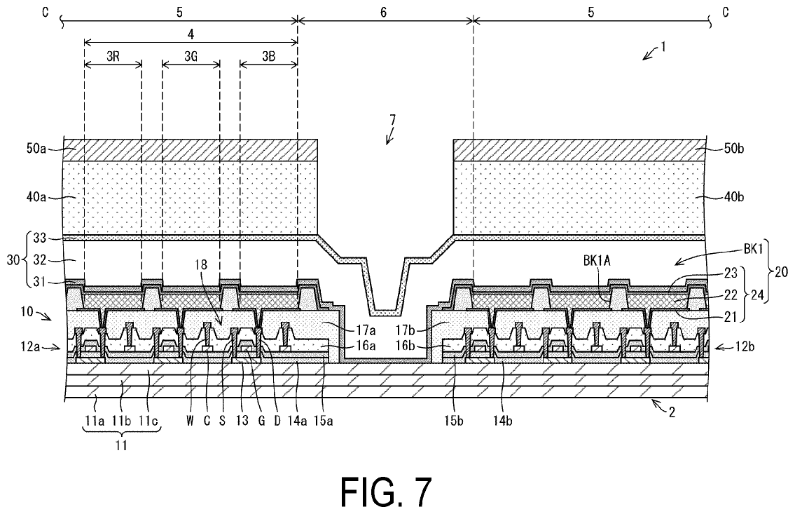

A description follows regarding another embodiment of the present disclosure, mainly with reference to FIGS. 7 to 10. Note that, in the present embodiment, the differences with the first embodiment will be described, and members having the same function as the members described in the first embodiment will be assigned the same reference signs and a description thereof will be omitted. Furthermore, the same modifications as those of the first embodiment can also be applied to the present embodiment.

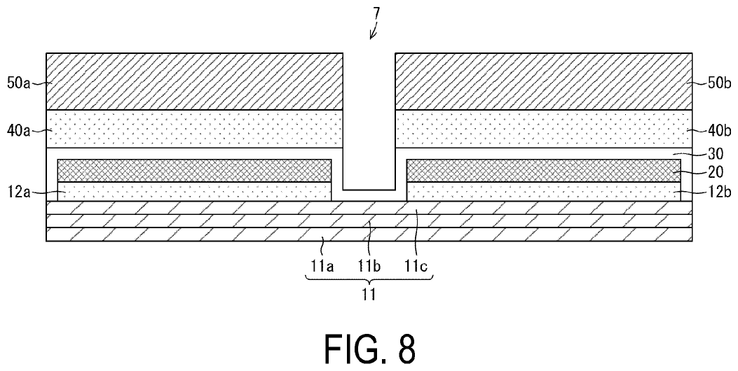

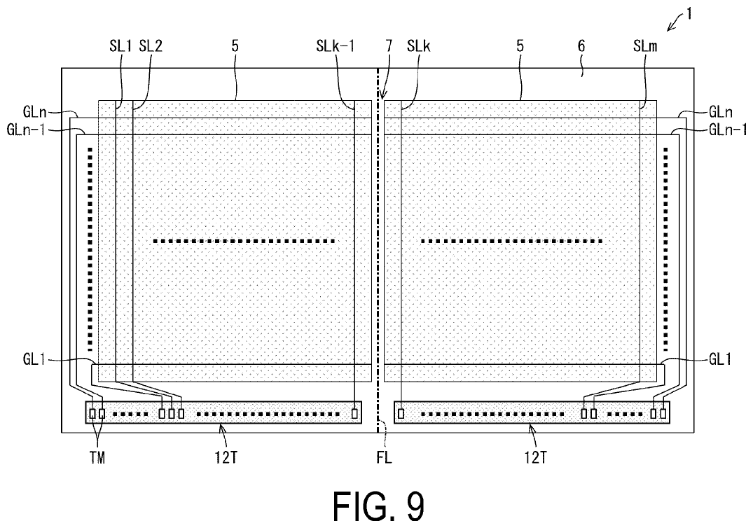

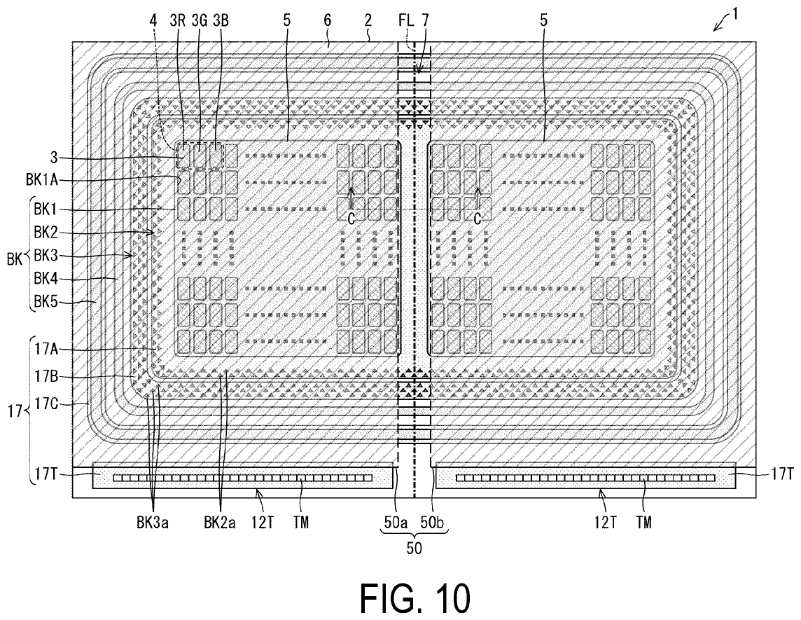

FIG. 7 is a cross-sectional view illustrating a schematic configuration of the periphery of the folding portion of the flexible display 1 according to the present embodiment. FIG. 8 is a cross-sectional view illustrating a schematic configuration of the flexible display 1 according to the present embodiment. FIG. 9 is a plan view illustrating a wiring configuration of the flexible display 1 according to the present embodiment. FIG. 10 is a plan view illustrating a schematic configuration of the flexible display 1 according to the present embodiment.

Note that FIG. 7 corresponds to a cross-sectional view of the flexible display 1 illustrated in FIG. 10 as viewed in the direction of arrows along a line C-C. In FIG. 10, for the convenience of illustration, the ratio of the frame region 6 with respect to the display region 5 is illustrated so as to be much larger than the actual ratio.

Furthermore, a cross-sectional view illustrating the schematic configuration of the periphery of the terminal portion 12T of the flexible display 1 according to the present embodiment is the same as FIG. 5. Thus, in the present embodiment, the cross-sectional view illustrating the schematic configuration of the periphery of the terminal portion 12T of the flexible display 1 according to the present embodiment is omitted.

The flexible display 1 according to the present embodiment is the same as the flexible display 1 according to the first embodiment, except for the points described below.

As illustrated in FIG. 7 to FIG. 10, in the flexible display 1 according to the present embodiment, in a plan view, the TFTs 18 and the organic EL elements 24 are provided avoiding the region in which the groove 7 that configures the folding portion is formed.

Furthermore, the inorganic layer of the folding portion is formed by the inorganic layers (the first inorganic layer 31 and the second inorganic layer 33) of the sealing film 30 and the barrier layer 11c, and no other inorganic layer is provided in the folding portion. In other words, the first metal layer, the second metal layer, the third metal layer, and the passivation films that cover those metal layers (in other words, the wires configured by those metal layers) and that include the inorganic insulating films 15 and 16 are provided avoiding the folding portion.

Thus, as illustrated in FIG. 9 and FIG. 10, in the flexible display 1, two of the display regions 5 are provided, in a plan view, with the folding portion (groove 7) disposed therebetween, and at the same time, the adhesive layers 40a and 40b and the cover layers 50a and 50b are provided in each of the display regions 5. The two display regions 5 form two screens of a two-page spread. The frame region 6 that configures a non-display region is provided between the two display regions 5.

Note that those TFTs 18, organic EL elements 24, various types of wires, and passivation films in the folding portion can be easily removed by photolithography, etching, or the like. In other words, in the present embodiment, in the formation process of the TFT layer 12 and the formation process of the OLED layer 20, more specifically, in the formation process of the TFTs 18, the formation process of the organic EL elements 24, the formation process of the wires, and the formation process of the passivation films, each of the layers is formed such that the TFTs 18, the organic EL elements 24, the various types of wire, and the passivation films are not formed in the folding portion.

Furthermore, in the flexible display 1, the wires are separated at the folding portion, and the wires are not provided in the folding portion. In other words, the wires of the flexible display 1 are provided avoiding the folding portion. As illustrated in FIG. 9 and FIG. 10, two of the terminal portions 12T for each of the wires are provided separately on either side of the folding portion, between each of the display regions 5 and the edge portion of the TFT substrate 10 (in other words, the edge portion of the OLED panel 2) while not overlapping with the folding portion.

Furthermore, in the present embodiment, in a plan view, two of the lattice-shaped banks BK1 that separate each of the sub pixels 3 are separated from each other with the folding portion (folding line FL) disposed therebetween, and the frame-shaped bank BK2, the frame-shaped bank BK3, the frame-shaped bank BK4, and the frame-shaped bank BK5 are each provided around the two lattice-shaped banks BK1 in this order from the inner side toward the outer side, on the outer side of two of the lattice-shaped banks BK1, while surrounding those two lattice-shaped banks BK1 and to cross the folding portion. Note that, also in the present embodiment, the lattice-shaped banks BK1 can be interpreted to mean the display regions 5 or groups of the organic EL elements 24.

Specifically, in the present embodiment, two of the first organic insulating film pattern portions 17A are separated from each other with the folding portion (folding line FL) disposed therebetween, and the second organic insulating film pattern portion 17B on which the frame-shaped bank BK3 is provided, and the third organic insulating film pattern portion 17C on which the frame-shaped bank BK4 and the frame-shaped bank BK5 are provided, are provided in this order from the inner side toward the outer side while surrounding those two first organic insulating film pattern portions 17A.

Thus, as illustrated in FIG. 7, FIG. 8, and FIG. 10, in the flexible display 1, the folding portion is formed by the support body 11 that is formed by the lower face film 11a, the resin layer 11b, and the barrier layer 11c, the second organic insulating film pattern portion 17B provided on the outer side of the display regions 5 of the support body 11, on which the frame-shaped bank BK3 is provided, the third organic insulating film pattern portion 17C on which the frame-shaped bank BK4 and the frame-shaped bank BK5 are provided, and the sealing film 30 formed by the first inorganic layer 31, the organic layer 32, and the second inorganic layer 33, and no other layer is provided in the folding portion.

Thus, in the present embodiment, in addition to the adhesive layer 40 and the cover layer 50, the TFT layer 12 is also bisected into TFT layers 12a and 12b with the folding portion disposed therebetween, and the TFT layers 12a and 12b are separated from each other in a plan view.

### Advantageous Effects

Thus, the flexible display 1 according to the present embodiment is easily folded at the folding portion, and further, the moisture-proof performance is obtained by layering the barrier layer 11c and the sealing film 30. Furthermore, with respect to the flexible display 1, even when the flexible display 1 is folded, almost no tensile stress is applied to the barrier layer 11c. Accordingly, the present embodiment can also obtain similar advantageous effects to those of the first embodiment.

Furthermore, according to the present embodiment, the inorganic layers of the folding portion are the first inorganic layer 31 and the second inorganic layer 33 that form the sealing film 30, and the barrier layer 11c, and no other inorganic layer is provided in the folding portion. In addition, the organic EL elements 24 are not provided in the folding portion either.

Thus, according to the present embodiment, while maintaining the moisture-proof performance, the thickness of the folding portion can be made even thinner, and the stress applied to the folding portion when the flexible display 1 is folded can be further reduced. Furthermore, according to the present embodiment, a breakage of the organic EL elements 24, the wires, and the passivation films of the folding portion, caused by the folding of the flexible display 1, can be inhibited.

Furthermore, according to the present embodiment, the frame-shaped banks BK2 to BK5, in particular, the frame-shaped banks BK4 and BK5 that are the organic layer stoppers, are not provided between the two display regions 5, and the frame-shaped banks BK2 to BK5 are each provided, while surrounding the two display regions 5, across the folding portion. As a result, the width of the non-display region (frame region 6) between the two display regions 5 can be made smaller (narrowed).

### Third Embodiment

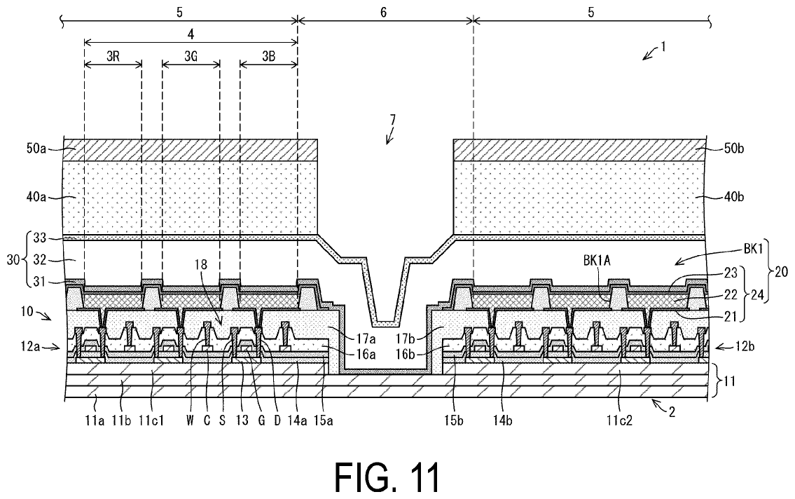

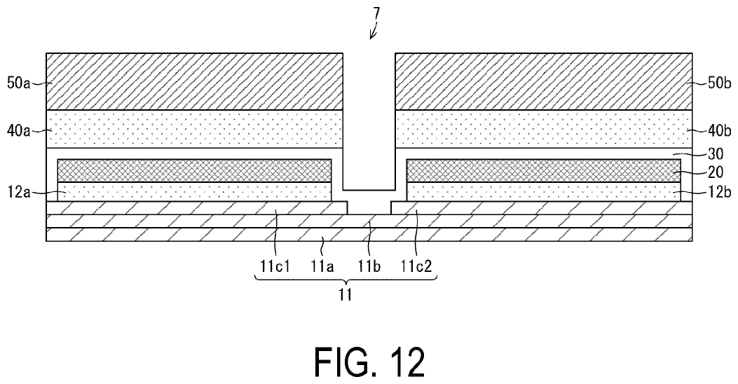

A description follows regarding yet another embodiment of the present disclosure, mainly with reference to FIG. 11 and FIG. 12. Note that, in the present embodiment, the differences with the first embodiment and the second embodiment will be described, and members having the same function as the members described in the first and second embodiments will be assigned the same reference signs and a description thereof will be omitted. Furthermore, the same modifications as those of the first and second embodiments can also be applied to the present embodiment.

FIG. 11 is a cross-sectional view illustrating a schematic configuration of the periphery of the folding portion of the flexible display 1 according to the present embodiment. FIG. 12 is a cross-sectional view illustrating a schematic configuration of the flexible display 1 according to the present embodiment.

Note that a plan view illustrating the wiring configuration of the flexible display 1 according to the present embodiment is the same as FIG. 9. Furthermore, a plan view illustrating a schematic configuration of the flexible display 1 according to the present embodiment is the same as FIG. 10, and a cross-sectional view illustrating the schematic configuration of the periphery of the terminal portion 12T of the flexible display 1 according to the present embodiment is the same as FIG. 5. FIG. 11 corresponds to a cross-sectional view of the flexible display 1 illustrated in FIG. 10 as viewed in the direction of arrows along the line C-C.

As illustrated in FIG. 11 and FIG. 12, the flexible display 1 according to the present embodiment is the same as the flexible display 1 according to the second embodiment, excepting that the barrier layer 11c is not provided in the region, in a plan view, in which the groove 7 that configures the folding portion is formed.

Furthermore, in the flexible display 1 according to the present embodiment, the inorganic layer of the folding portion is formed by the inorganic layers (the first inorganic layer 31 and the second inorganic layer 33) of the sealing film 30, and no other inorganic layer is provided in the folding portion.

Note that, similarly to the TFTs 18, the organic EL elements 24, the various types of wire, and the passivation films in the folding portion, the barrier layer 11c in the folding portion can be easily removed by photolithography, etching, or the like. In other words, in the present embodiment, in the formation process of the support body 11, the formation process of the TFT layer 12, and the formation process of the OLED layer 20, more specifically, in the formation process of the barrier layer 11c, the formation process of the TFTs 18, the formation process of the organic EL elements 24, the formation process of the wires, and the formation process of the passivation films, each of the layers is formed such that the barrier layer 11c, the TFTs 18, the organic EL elements 24, the various types of wire, and the passivation films are not formed in the folding portion.

Thus, in the present embodiment, in addition to the adhesive layer 40, the cover layer 50, and the TFT layer 12, the barrier layer 11c is also bisected into barrier layers 11c1 and 11c2 with the folding portion disposed therebetween, and the barrier layers 11c1 and 11c2 are separated from each other in a plan view. Thus, the barrier layer 11c1 and the barrier layer 11c2 are each provided in an island shape and separated from each other, in the central portion of each of the sides along the longitudinal direction of the flexible display 1, such that respective end faces of the barrier layers 11c1 and 11c2 face each other along the lateral direction.

### Advantageous Effects

According to the present embodiment, the sealing film 30 is provided in the folding portion, and the barrier layers 11c1 and 11c2 are provided in the regions excluding the folding portion. As a result, while maintaining the moisture-proof performance, the thickness of the folding portion can be made even thinner, and the stress applied to the folding portion when the flexible display 1 is folded can be further reduced. Accordingly, the present embodiment can also obtain similar advantageous effects to those of the first and second embodiments.

Furthermore, according to the present embodiment, as described above, since the barrier layers 11c1 and 11c2 are not provided in the folding portion (in other words, since the barrier layers 11c1 and 11c2 are provided avoiding the folding portion), the barrier layer 11 does not break due to the folding of the flexible display 1, and thus, the reliability can be further improved.

### Fourth Embodiment

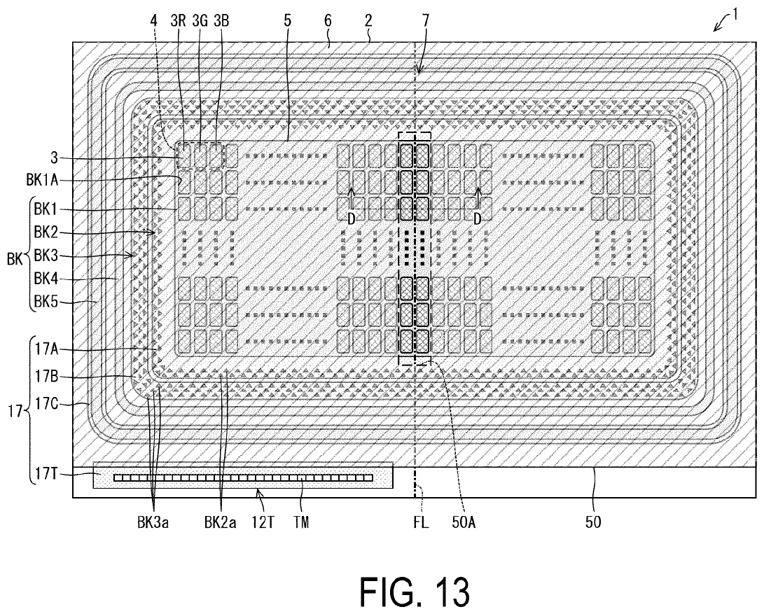

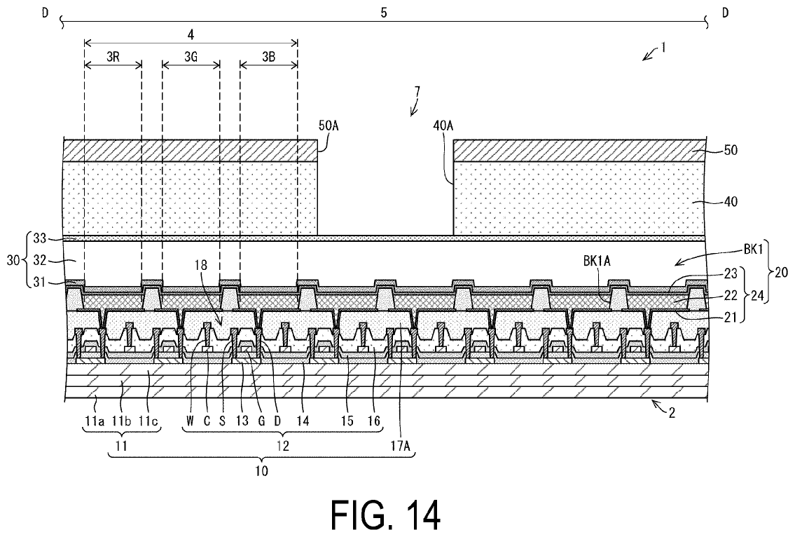

A description follows regarding yet another embodiment of the present disclosure, mainly with reference to FIG. 13 and FIG. 14. Note that, in the present embodiment, the differences with the first to third embodiments will be described, and members having the same function as the members described in the first to third embodiments will be assigned the same reference signs and a description thereof will be omitted. Furthermore, the same modifications as those of the first to third embodiments can also be applied to the present embodiment.

FIG. 13 is a plan view illustrating a schematic configuration of the flexible display 1 according to the present embodiment. FIG. 14 is a cross-sectional view illustrating a schematic configuration of the periphery of the folding portion of the flexible display 1 according to the present embodiment.

Note that FIG. 14 corresponds to a cross-sectional view of the flexible display 1 illustrated in FIG. 13 as viewed in the direction of arrows along a line D-D. In FIG. 13, for the convenience of illustration, the ratio of the frame region 6 with respect to the display region 5 is illustrated so as to be much larger than the actual ratio.

As illustrated in FIG. 13 and FIG. 14, the flexible display 1 according to the present embodiment is different from the flexible display 1 according to the first to third embodiments in that the cover layer 50 includes an opening 50A in a region, of the folding portion, that is adjacent to the organic EL elements 24 in a plan view, and at the same time, the adhesive layer 40 includes an opening 40A in the region in which the opening 50A is provided in a plan view (more specifically, the region of the folding portion adjacent to the organic EL elements 24 in a plan view).

Note that, in FIG. 13 and FIG. 14, an example is illustrated of a case in which the adhesive layer 40 including the opening 40A and the cover layer 50 including the opening 50A are provided in place of the adhesive layers 40a and 40b and the cover layers 50a and 50b.

However, the present embodiment is not limited to this example, and it goes without saying that, in the second or third embodiment, the adhesive layer 40 including the opening 40A and the cover layer 50 including the opening 50A may be provided in place of the adhesive layers 40a and 40b and the cover layers 50a and 50b.

Note that, in the example illustrated in FIG. 13 and FIG. 14 (in other words, in the flexible display 1 according to the first embodiment), the region of the folding portion adjacent to the organic EL elements 24 in a plan view indicates the region of the folding portion corresponding to the display region 5 in a plan view. Furthermore, in the flexible display 1 according to the second and third embodiments, the region of the folding portion adjacent to the organic EL elements 24 in a plan view indicates the region of the folding portion adjacent to the display regions 5 (in other words, the frame region 6 between the adjacent display regions 5).

Furthermore, in FIG. 13 and FIG. 14, the example is illustrated of the case in which the openings 40A and 50A are provided only in the region of the folding portion adjacent to the organic EL elements 24 in a plan view, but the present embodiment is not limited to this example.

It is sufficient that the openings 40A and 50A be provided at least in the region of the folding portion adjacent to the organic EL elements 24 in a plan view.

In this way, in the present embodiment, the adhesive layer 40 and the cover layer 50 are provided avoiding the region of the folding portion adjacent to the organic EL elements 24 in a plan view, and the adhesive layer 40 and the cover layer 50 are each connected at both end portions of the folding portion.

In the first to third embodiments, the flexible display 1 according to the present embodiment can be easily produced, in the formation process of the adhesive layer 40 and the cover layer 50, by preparing a functional film including the cover layer 50 including the opening 50A and adhesive layer 40 provided on one surface of the cover layer 50 and bonding the cover layer 50 onto the sealing film 30.

### Advantageous Effects

According to the present embodiment, as a result of the groove 7 that is configured by the openings 40A and 50A being provided in the folding portion, the flexible display 1 can be easily folded at the groove 7. Furthermore, since the stress acting on each of the layers that forms the folding portion can be reduced in the region in which the openings 40A and 50A are formed, also in the present embodiment, when the flexible display 1 is folded, the film breakage of the barrier layer 11c and the like does not occur in the folding portion, in particular, in the region in which the openings 40A and 50A are formed. Thus, the lighting failure of the organic EL element 24 can be inhibited.

### Fifth Embodiment

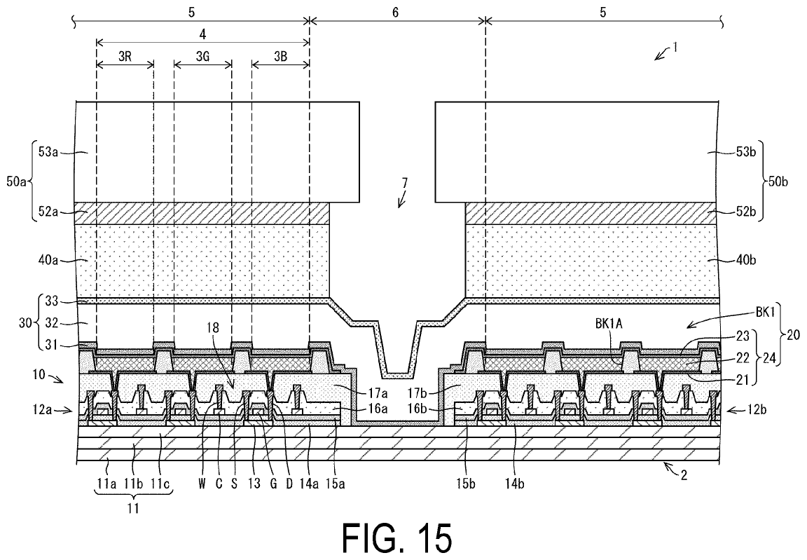

A description follows regarding another embodiment of the present disclosure, mainly with reference to FIG. 15 to FIG. 18. Note that, in the present embodiment, the differences with the first to fourth embodiments will be described, and members having the same function as the members described in the first to fourth embodiments will be assigned the same reference signs and a description thereof will be omitted. Furthermore, the same modifications as those of the first to fourth embodiments can also be applied to the present embodiment.

FIG. 15 is a cross-sectional view illustrating a schematic configuration of the periphery of the folding portion of the flexible display 1 according to the present embodiment.

Note that, in the present embodiment, although a description will be made using a modified example of the flexible display 1 according to the second embodiment as an example, it goes without saying that the following modifications may be made to the first, third, or fourth embodiment.

In the flexible display 1 according to the present embodiment, to minimize the width of the groove 7, namely, the width of the non-display region (frame region 6) between the adjacent display regions 5, light guides 53a and 53b are provided on a display surface of the OLED panel 2, as described in FIG. 15. This allows a part of the light emitted from the display regions 5 to be guided to a region between the adjacent display regions 5 in which the organic EL elements 24 (in other words, the sub pixels 3) are not formed, and the light guide 53a and 53b allow a part of the image in the display regions 5 to be displayed in the region in which the light emitting elements are not formed.

As illustrated in FIG. 15, the flexible display 1 according to the present embodiment is the same as the flexible display 1 according to the second embodiment, for example, excepting that the flexible display 1 according to the present embodiment includes, as the cover layer 50a, a polarizing film 52a and the light guide 53a provided on the polarizing film 52a, and at the same time, includes, as the cover layer 50b, a polarizing film 52b and the light guide 53b provided on the polarizing film 52b. Note that the polarizing films 52a and 52b and the light guides 53a and 56b are respectively bonded to each other by an adhesive layer (not illustrated).

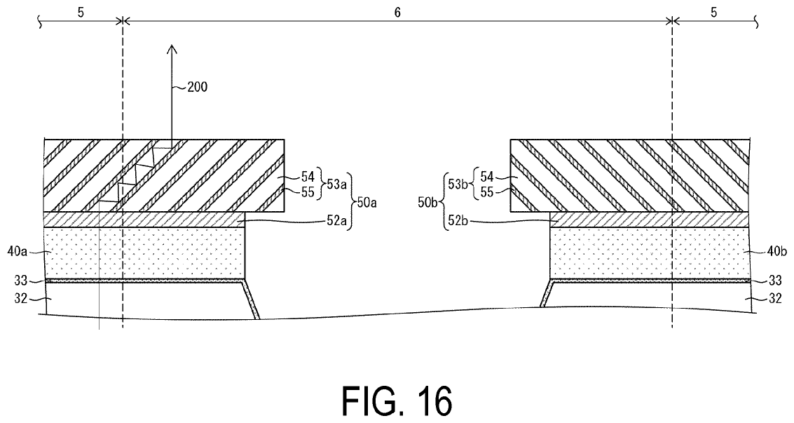

FIG. 16 is a cross-sectional view illustrating an example of the light guides 53a and 53b used in the flexible display 1 according to the present embodiment.

The flexible display 1 illustrated in FIG. 16 includes, as the light guides 53a and 53b, a functional film layer configured by a sheet-shaped layered body, in which light guide layers 54 and reflective layers 55 are repeatedly layered in the thickness direction thereof (more specifically, in the direction orthogonal to the propagation direction of the light) while parallel to each other. The light guide layer 54 and reflective layer 55 are bonded to each other by an adhesive layer (not illustrated), for example.

A light-transmissive layer formed from polyethylene terephthalate, an acrylic resin, and a transparent resin such as a cycloolefin resin can be used as the light guide layer 54. Furthermore, a metal layer formed from silver, aluminum, and the like can be used as the reflective layer 55.

In this case, light guide portions of the light guides 53a and 53b are formed by the light guide layers 54, reflective layers 55, and the adhesive layers (not illustrated) that bonds the light guide layers 54 and reflective layers 55 together. Each of those layers (in other words, each of the light guide portions) is formed while not extending in the normal direction with respect to the display surface of the flexible display 1, but extending obliquely from the normal direction with respect to the display surface of the flexible display 1.

Thus, an interface of each of the layers that forms the light guide portions of the light guides 53a and 53b are provided while inclined with respect to incident surfaces of the light guides 53a and 53b, on which the light emitted from the organic EL elements 24 in each of the display regions 5 is incident, and with respect to emitting surfaces thereof, from which the light is emitted.

In this case, the light incident on the light guides 53a and 53b from one of end faces of the light guide layers 54 is reflected by the reflective layers 55, propagates inside the light guide layers 54, and is emitted from the other end face of the light guide layers 54.

As described above, as a result of guiding a part of the light emitted from each of the display regions 5 onto the frame region 6 between the adjacent display regions 5 using the light guide portions provided while inclined with respect to the display surface of the flexible display 1, the light guides 53a and 53b allow a part of the image in each of the display regions 5 to be displayed in (shifted to) the frame region 6, when the flexible display 1 is viewed from above the light guides 53a and 53b.

Note that the light guides 53a and 53b are not limited to the above-described configuration, may be layered bodies in which two or more types of light-transmissive layers that have a different refractive index from each other are layered while being parallel to each other.

More specifically, the light guides 53a and 53b, may include, as the light guide layers 54, the light-transmissive layers formed from a transparent resin, and may also include, as the reflective layers 55, the light-transmissive layers formed from a transparent resin that has a refractive index lower than that of the light guide layers 54.

In this case, the light guide layers 54 and reflective layers 55 may be in direct contact with each other, or the adhesive layers may be interposed therebetween.

In this case, since the refractive index of the light-transmissive layers that are the light guide layers 54 is greater than the refractive index of the light-transmissive layers that are the reflective layers 55, the light incident on the light guide layers 54 from the organic EL elements 24 is all reflected by the interfaces between the light guide layers 54 and reflective layers 55, and propagates inside the light guide layers 54.

Thus, in this case also, the light incident on the light guides 53a and 53b from one of the end faces of the light guide layers 54 is reflected by the interfaces with the light-transmissive layers that function as the reflective layers 55, propagates inside the light guide layers 54, and is emitted from the other end face of the light guide layers 54.

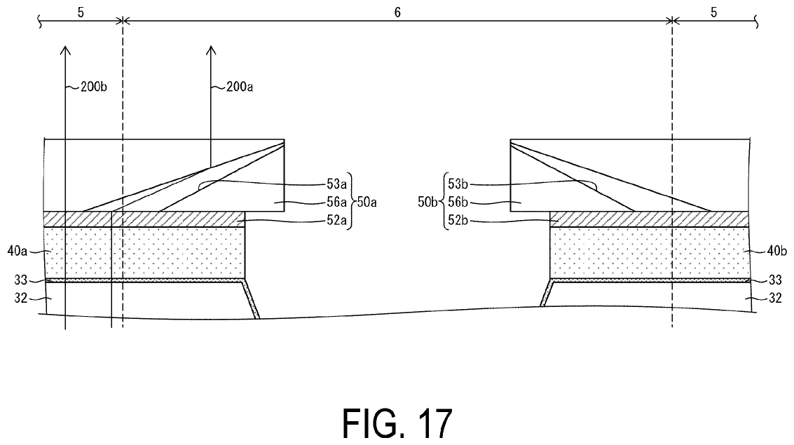

FIG. 17 is a cross-sectional view illustrating another example of the light guides 53a and 53b used in the flexible display 1 according to the present embodiment.

The light guides 53a and 53b may be provided over the entire surface of each of the display regions 5, or, as illustrated in FIG. 17, may be provided only in the frame region 6 and a part of the region, adjacent to the frame region 6, of the display regions 5.

The light guides 53a and 53b illustrated in FIG. 17 are the same as the light guides 53a and 53b illustrated in FIG. 16, excepting that the light guides 53a and 53b are formed in a triangular prismatic shape in which the emitting surfaces of the light emitted from the light guides 53a and 53b are inclined with respect to the display surface of the flexible display 1, although the incident surfaces of the light emitted from the organic EL elements 24 are parallel to the display surface of the flexible display 1.

The flexible display 1 illustrated in FIG. 17 includes, as the cover layer 50a, the polarizing film 52a, the light guide 53a provided on the polarizing film 52a, and a light-transmissive cover sheet 56a that covers the display region 5, on which the light guide 53a is layered, and the emitting surface of the light guide 53a. Furthermore, the flexible display 1 illustrated in FIG. 17 includes, as the cover layer 50b, the polarizing film 52b, the light guide 53b provided on the polarizing film 52b, and a light-transmissive cover sheet 56b that covers the display region 5 on which the light guide 53b is layered and the emitting surface of the light guide 53b.

Note that the light guides 53a and 53b and the light-transmissive cover sheets 56a and 56b may be respectively bonded to each other by an adhesive layer, or may be fixed to each other with an air layer interposed therebetween. The light-transmissive cover sheets 56a and 56b are used for protecting and leveling out the surface of the flexible display 1. Thus, the light-transmissive cover sheets 56a and 56b may not be necessary.

Also in this case, as a result of guiding a part of the light emitted from each of the display regions 5 onto the frame region 6 between the adjacent display regions 5 using the light guides 53a and 53b, a part of the image in each of the display regions 5 can be displayed in (shifted to) the frame region 6, when the flexible display 1 is viewed from above the light guides 53a and 53b.

However, when the light guides 53a and 53b having the triangular prismatic shape, as illustrated in FIG. 17, are used, a shift amount of the display image becomes different depending on positions of the sub pixels 3. Thus, the shift amount of the display image needs to be changed in accordance with a distance, on the incident surface of each of the light guides 53a and 53b, from an end portion on each of a display region 5 side to an end portion on the other side of each of the display regions 5. Note that the shift amount may be changed using a look up table (LUT) that is associated with the pixel positions of the display regions 5, or the shift amount corresponding to the positions of the sub pixels 3 may be calculated each time.

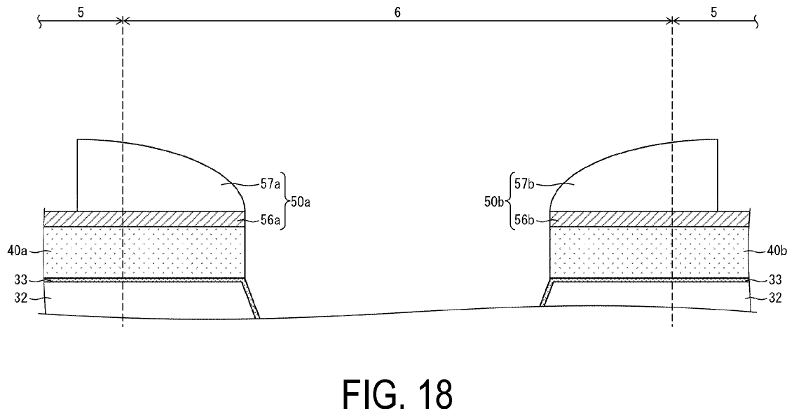

FIG. 18 is a cross-sectional view illustrating yet another example of the light guides 53a and 53b used in the flexible display 1 according to the present embodiment.

The flexible display 1 illustrated in FIG. 18 includes, as the light guides 53a and 53b, cylindrical lenses 57a and 57b, for example, in the frame region 6 and a part of the region of the display regions 5 adjacent to the frame region 6.

The cylindrical lenses 57a and 57b each have a curved emitting surface, and have a shape that is inclined with respect to the display regions 5. Thus, the light emitted from the display regions 5 provided with the cylindrical lenses 57a and 57b is refracted when it passes through the cylindrical lenses 57a and 57b, and a part of the image in each of the display regions 5 is displayed in (shifted to) the frame region 6, when the flexible display 1 is viewed from above the light guides 53a and 53b.

According to the present embodiment, as described above, a part of the light emitted from the display regions 5 adjacent to each other with the folding portion disposed therebetween can be guided to the region (frame region 6), in which the light emitting elements are not formed, between the display regions 5 adjacent to each other with the folding portion disposed therebetween. Thus, according to the present embodiment, a part of the images each displayed in the display regions 5 adjacent to each other with the folding portion disposed therebetween can be displayed in (shifted to) the frame region 6 between the display regions 5 adjacent to each other with the folding portion disposed therebetween. Thus, according to the present embodiment, the width of the non-display region between the adjacent display regions 5 can be made substantially smaller.

### Conclusion

A display device (the flexible display 1) according to a first aspect of the present disclosure includes at least one folding portion; a support body (the TFT substrate 10) including a barrier layer (the barrier layer 11c, the barrier layers 11c1 and 11c2); a plurality of optical elements (the organic EL elements 24, for example) provided on the support body; a sealing film (the sealing film 30) sealing the plurality of optical elements and including a plurality of inorganic layers (the first inorganic layer 31, the second inorganic layer 33) superimposed on each other and at least one organic layer (the organic layer 32) sandwiched between two inorganic layers of the plurality of inorganic layers; an adhesive layer 40 (the adhesive layer 40, the adhesive layers 40a and 40b) provided on the sealing film 30; and a cover layer (the cover layer 50, the cover layers 50a and 50b) provided on the adhesive layer and including a functional film layer. In a plan view, the adhesive layer and the cover layer are provided avoiding at least a region of the at least one folding portion adjacent to the plurality of optical elements.

In the display device according to a second aspect of the present disclosure, in the above-described first aspect, the adhesive layer and the cover layer may be each divided into a plurality of adhesive layers and a plurality of cover layers, respectively, each having an island shape in a plan view, and in a plan view, the plurality of adhesive layers (the adhesive layers 40a and 40b) divided and each having an island shape may be separated with each other with the at least one folding portion disposed between the plurality of adhesive layers, and the plurality of cover layers (the cover layers 50a and 50b) divided and each having an island shape may be separated with each other with the at least one folding portion disposed between plurality of cover layers.

In the display device according to a third aspect of the present disclosure, in the above-described first aspect, in a plan view, the adhesive layer and the cover layer may each include an opening (the openings 40A and 50A) in the region of the at least one folding portion adjacent to the plurality of optical elements.

In the display device according to a fourth aspect of the present disclosure, in any one of the above-described first to third aspects, the plurality of optical element may each include a first electrode (the first electrode 21), a second electrode (the second electrode 23), and a functional layer (the organic EL layer 22) provided between the first electrode and the second electrode , and the second electrode may be provided across the at least one folding portion.

In the display device according to a fifth aspect of the present disclosure, in any one of the above-described first to fourth aspects, the display device may further include a wire (the gate line GL) across the at least one folding portion. A terminal portion (the terminal portion 12T) including terminals (the terminals TM) for wires including the wire may be formed between an edge portion of the support body and the display region (the display region 5) including the plurality of optical elements provided in the display region while not overlapping with the at least one folding portion.

In the display device according to a sixth aspect of the present disclosure, in any one of the above-described first to third aspects, the plurality of optical elements may be provided avoiding the at least one folding portion, and a plurality of display regions including the plurality of optical elements provided in the plurality of display region may be provided with the at least one folding portion disposed between the plurality of display regions.

In the display device according to a seventh aspect of the present disclosure, in the above-described sixth aspect, an inorganic layer provided on the at least one folding portion may include the barrier layer and the plurality of inorganic layers that form the sealing film.

In the display device according to an eighth aspect of the present disclosure, in the above-described sixth aspect, in a plan view, the barrier layer may be divided into a plurality of barrier layers each having an island shape, the plurality of barrier layers (the barrier layers 11c1 and 11c2) divided and each having an island shape may be separated with each other with the at least one folding portion disposed between the plurality of barrier layers in a plan view, and an inorganic layer provided on the at least one folding portion may include the plurality of inorganic layers that form the sealing film.

In the display device according to a ninth aspect of the present disclosure, in any one of the above-described sixth to eighth aspects, a frame-shaped bank (the bank BK4) overlapping with an edge of the at least one organic layer may be provided across the at least one folding portion and surround the plurality of display regions.

In the display device according to a tenth aspect of the present disclosure, in any one of the above-described sixth to ninth aspects, the display device may further include a plurality of wires separated at the at least one folding portion. A terminal portion (the terminal portion 12T) including respective terminals (the terminals TM) for the plurality of wires formed in the terminal portion may be provided between an edge portion of the support body and each of the plurality of display regions while not overlapping with the at least one folding portion.

In the display device according to a eleventh aspect of the present disclosure, in any one of the above-described first to tenth aspects, the sealing film may include, as the plurality of inorganic layers, a first inorganic layer (the first inorganic layer 31) and a second inorganic layer (the second inorganic layer 33), and may also include, as the at least one organic layer, an organic layer(the single organic layer 32) provided between the first inorganic layer and the second inorganic layer.

In the display device according to a twelfth aspect of the present disclosure, in any one of the above-described first to eleventh aspects, the display device may further include a light guide (the light guides 53a and 53b, the cylindrical lenses 57a and 57b) configured to guide a part of light emitted from each of the plurality of optical elements adjacent to each other with the at least one folding portion disposed between the plurality of optical elements in a plan view, to a region between the plurality of optical elements adjacent to each other with the at least one folding portion disposed between the plurality of optical elements.

In a method for producing a display device (the flexible display 1) according to a thirteenth aspect of the present disclosure, the display device including a support body (the TFT substrate 10) including a barrier layer (the barrier layer 11c, the barrier layers 11c1 and 11c2), a plurality of optical elements (the organic EL elements 24, for example) provided on the support body, a sealing film (the sealing film 30) sealing the plurality of optical elements and including a plurality of inorganic layers (the first inorganic layer 31, the second inorganic layer 33) superimposed on each other and at least one organic layer (the organic layer 32) sandwiched between two inorganic layers of the plurality of inorganic layers, an adhesive layer (the adhesive layer 40, the adhesive layers 40a and 40b) provided on the sealing film 30, and a cover layer (the cover layer 50, the cover layers 50a and 50b) provided on the adhesive layer and including a functional film layer, and further including at least one folding portion, the method includes forming the adhesive layer and the cover layer while avoiding at least a region of the at least one folding portion adjacent to the plurality of optical elements in a plan view.

The present disclosure is not limited to each of the embodiments stated above, and various modifications may be implemented within a range not departing from the scope of the claims. Embodiments obtained by appropriately combining technical approaches stated in each of the different embodiments also fall within the scope of the technology of the present disclosure. Moreover, novel technical features may be formed by combining the technical approaches stated in each of the embodiments.

### REFERENCE SIGNS LIST

1 Flexible display (display device)
2 OLED panel
3 Sub pixel
4 Pixel
5 Display region
6 Frame region
7 Groove
10 TFT substrate (support body)
11 Support body
11a Lower face film
11b Resin layer
11c, 11c1, 11c2 Barrier layer
12, 12a, 12b TFT layer
12T Terminal portion
13 Semiconductor layer
14 Gate insulating film
15, 16 Inorganic insulating film
17 Organic insulating film
17A First organic insulating film pattern portion
17B Second organic insulating film pattern portion
17C Third organic insulating film pattern portion
17T Terminal portion organic insulating film pattern portion
18 TFT
20 OLED layer
21 First electrode
22 Organic EL layer
23 Second electrode
24 Organic EL element (optical element)
30 Sealing film
31 First inorganic layer
32 Organic layer
33 Second inorganic layer
40, 40a, 40b Adhesive layer
40A, 50A Opening
50, 50a, 50b Cover layer
51a, 51b Protective film
52a, 52b Polarizing film
53a, 53b Light guide
54 Light guide layer
55 Reflective layer
56 Light-transmissive cover sheet
57 Cylindrical lens (light guide)
BK, BK1, BK2, BK3, BK4, BK5 Bank
BK2a, BK3a Dot-shaped bank
GL Gate line (wire)
SL Source line
W Wire
TM Terminal
FL Folding line

1-3 (canceled)

4. A display device having at least one folding portion comprising,
a support body including a barrier layer;
a plurality of optical elements provided on the support body;
a sealing film sealing the plurality of optical elements and including a plurality of inorganic layers superimposed on each other and at least one organic layer sandwiched between two inorganic layers of the plurality of inorganic layers;
an adhesive layer provided on the sealing film; and
a cover layer provided on the adhesive layer and including a functional film layer,
wherein, in a plan view, the adhesive layer and the cover layer are provided avoiding at least a region of the at least one folding portion adjacent to the plurality of optical elements,
the plurality of optical elements each include a first electrode, a second electrode, and a functional layer provided between the first electrode and the second electrode, and
the second electrode is provided across the at least one folding portion.

5-6 (canceled)

7. A display device having at least one folding portion comprising:
a support body including a barrier layer;
a plurality of optical elements provided on the support body;
a sealing film sealing the plurality of optical elements and including a plurality of inorganic layers superimposed on each other and at least one organic layer sandwiched between two inorganic layers of the plurality of inorganic layers;
an adhesive layer provided on the sealing film; and
a cover layer provided on the adhesive layer and including a functional film layer,
wherein, in a plan view, the adhesive layer and the cover layer are provided avoiding at least a region of the at least one folding portion adjacent to the plurality of optical elements,
the plurality of optical elements are provided avoiding the at least one folding portion,
a plurality of display regions including the plurality of optical elements provided in the plurality of display regions are provided with the at least one folding portion disposed between the plurality of display regions, and
an inorganic layer provided on the at least one folding portion includes the barrier layer and the plurality of inorganic layers that form the sealing film.

8. (canceled)

9. A display device having at least one folding portion comprising:
a support body including a barrier layer;
a plurality of optical elements provided on the support body;
a sealing film sealing the plurality of optical elements and including a plurality of inorganic layers superimposed on each other and at least one organic layer sandwiched between two inorganic layers of the plurality of inorganic layers;
an adhesive layer provided on the sealing film; and
a cover layer provided on the adhesive layer and including a functional film layer,
wherein, in a plan view, the adhesive layer and the cover layer are provided avoiding at least a region of the at least one folding portion adjacent to the plurality of optical elements,
the plurality of optical elements are provided avoiding the at least one folding portion,
a plurality of display regions including the plurality of optical elements provided in the plurality of display regions are provided with the at least one folding portion interposed between the plurality of display regions, and
a frame-shaped bank overlapping with an edge of the at least one organic layer is provided across the at least one folding portion and surrounding the plurality of display regions.

10-13 (canceled)

14. The display device according to claim 4, further comprising:
a light guide configured to guide a part of light emitted from each of the plurality of optical elements adjacent to each other with the at least one folding portion disposed between the plurality of optical elements in a plan view, to a region between the plurality of optical elements adjacent to each other with the at least one folding portion disposed between the plurality of optical elements.

15. The display device according to claim 7, further comprising:
a light guide configured to guide a part of light emitted from each of the plurality of optical elements adjacent to each other with the at least one folding portion disposed between the plurality of optical elements in a plan view, to a region between the plurality of optical elements adjacent to each other with the at least one folding portion disposed between the plurality of optical elements.

16. The display device according to claim 9 further comprising:
a light guide configured to guide a part of light emitted from each of the plurality of optical elements adjacent to each other with the at least one folding portion disposed between the plurality of optical elements in a plan view, to a region between the plurality of optical elements adjacent to each other with the at least one folding portion disposed between the plurality of optical elements.

17. The display device according to claim 4,
wherein the plurality of optical elements are provided avoiding the at least one folding portion, and a plurality of display regions including the plurality of optical elements provided in the plurality of display regions are provided with the at least one folding portion disposed between the plurality of display regions.

18. The display device according to claim 17,
wherein an inorganic layer provided on the at least one folding portion includes the barrier layer and the plurality of inorganic layers that forms the sealing film.

19. The display device according to claim 17,
wherein a frame-shaped bank overlapping with an edge of the at least one organic layer is provided surrounding the plurality of display regions and across the at least one folding portion.

20. The display device according to claim 18,
wherein a frame-shaped bank overlapping with an edge of the at least one organic layer is provided surrounding the plurality of display regions and across the at least one folding portion.

21. The display device according to claim 17 further comprising:
a light guide configured to guide a part of light emitted from each of the plurality of optical elements adjacent to each other with the at least one folding portion disposed between the plurality of optical elements in a plan view, to a region between the plurality of optical elements adjacent to each other with the at least one folding portion disposed between the plurality of optical elements.

22. The display device according to claim 18 further comprising:
a light guide configured to guide a part of light emitted from each of the plurality of optical elements adjacent to each other with the at least one folding portion disposed between the plurality of optical elements in a plan view, to a region between the plurality of optical elements adjacent to each other with the at least one folding portion disposed between the plurality of optical elements.

23. The display device according to claim 19 further comprising:
a light guide configured to guide a part of light emitted from each of the plurality of optical elements adjacent to each other with the at least one folding portion disposed between the plurality of optical elements in a plan view, to a region between the plurality of optical elements adjacent to each other with the at least one folding portion disposed between the plurality of optical elements.

24. The display device according to claim 20 further comprising:
a light guide configured to guide a part of light emitted from each of the plurality of optical elements adjacent to each other with the at least one folding portion disposed between the plurality of optical elements in a plan view, to a region between the plurality of optical elements adjacent to each other with the at least one folding portion disposed between the plurality of optical elements.

25. The display device according to claim 4,
wherein the adhesive layer and the cover layer are divided into a plurality of adhesive layers and a plurality of cover layers, respectively, each having an island shape in a plan view, and
in a plan view, the plurality of adhesive layers divided and each having an island shape are separated with each other with the at least one folding portion disposed between the plurality of adhesive layers, and the plurality of cover layers divided and each having an island shape are separated with each other with the at least one folding portion disposed between the plurality of cover layers.

26. The display device according to claim 4,
wherein, in a plan view, the adhesive layer and the cover layer each include an opening in the region of the at least one folding portion adjacent to the plurality of optical elements.

27. The display device according to claim 4 further comprising:
a wire disposed across the at least one folding portion,
wherein a terminal portion including terminals for wires including the wire is formed between an edge portion of the support body and the display region including the plurality of optical elements provided in the display region while not overlapping with the at least one folding portion.

28. The display device according to claim 4,
wherein the sealing film includes, as the plurality of inorganic layers, a first inorganic layer and a second inorganic layer, and also includes, as the at least one organic layer, an organic layer provided between the first inorganic layer and the second inorganic layer.

29. The display device according to claim 7,
wherein, in a plan view, the barrier layer is divided into a plurality of barrier layers each having an island shape, the plurality of barrier layers divided and each having an island shape are separated with each other with the at least one folding portion disposed between the plurality of barrier layers in a plan view, and an inorganic layer provided on the at least one folding portion includes the plurality of inorganic layer that form the sealing film.

30. The display device according to claim 7 further comprising:
a plurality of wires separated at the at least one folding portion,
wherein a terminal portion including respective terminals for the plurality of wires formed in the terminal portion is provided between an edge portion of the support body and each of the plurality of display regions while not overlapping with the at least one folding portion.
